(19) United States
(12) Patent Application Publication
(10) Pub. No.: US 2016/0005599 A1
(43) Pub. Date: Jan. 7, 2016

(54) METHOD FOR FORMING ALIGNED OXIDE SEMICONDUCTOR WIRE PATTERN AND ELECTRONIC DEVICE USING SAME

(71) Applicant: POSTECH ACADEMY-INDUSTRY FOUNDATION, Pohang (KR)

(72) Inventors: Tae-Woo LEE, Pohang (KR); Sung-Yong MIN, Gwangju (KR)

(21) Appl. No.: 14/768,265

(22) PCT Filed: Feb. 18, 2014
(86) PCT No.: PCT/KR2014/001316

§ 371 Date: Aug. 17, 2015

(30) Foreign Application Priority Data
Feb. 18, 2013 (KR) 10-2013-0017017
Feb. 18, 2013 (KR) 10-2013-0017217
Sep. 10, 2013 (KR) 10-2013-0108357

(51) Int. Cl. H01L 21/02; H01L 29/06; H01L 29/786; H01L 31/0296; H01L 31/032; H01L 31/0352; H01L 31/06; H01L 31/18; H01L 33/00; H01L 33/28; H01L 33/26; H01L 33/24; H01S 5/30; H01L 41/37; H01L 41/187; H01L 29/24

(52) U.S. Cl. CPC H01L 21/02565; H01L 21/02628; H01L 21/02554; H01L 21/02603; H01L 29/24; H01L 29/0669; H01L 29/7869; H01L 31/0296; H01L 31/032; H01L 31/035281; H01L 31/06; H01L 31/18; H01L 31/1828; H01L 33/0041; H01L 33/28; H01L 33/26; H01L 33/24; H01L 33/0087; H01L 33/005; H01S 5/3018; H01S 5/30; H01L 41/37; H01L 41/1875; H01L 41/1878; H01L 41/187

(57) ABSTRACT

A method for forming an aligned oxide semiconductor wire pattern includes: dissolving an oxide semiconductor precursor and an organic polymer in distilled water or an organic solvent to provide a composite solution of an oxide semiconductor precursor/organic polymer; continuously discharging the composite solution of the oxide semiconductor precursor/organic polymer in a vertical upper direction from a substrate to align an oxide semiconductor precursor/organic polymer composite wire on the substrate; and heating the oxide semiconductor precursor/organic polymer composite wire to remove the organic polymer and converting the oxide semiconductor precursor into an oxide semiconductor to form an aligned oxide semiconductor wire pattern.

### CROSS-REFERENCE TO RELATED APPLICATION

This application claims priority to and the benefit of Korean Patent Application Nos. 10-2013-0017017 and 10-2013-0017217 filed in the Korean Intellectual Property Office on Feb. 18, 2013, and Korean Patent Application No. 10-2013-0108357 filed in the Korean Intellectual Property Office on Sep. 10, 2013, the entire contents of which are incorporated herein by reference.

### BACKGROUND OF THE INVENTION

(a) Field of the Invention

The present invention relates to a method for forming an aligned oxide semiconductor wire pattern and an electronic device comprising same.

(b) Description of the Related Art

Usefulness of a conventional inorganic semiconductor nanowire has increased due to its excellent electrical characteristics and the need for flexible electronic devices. In addition, research on an electronic device using the inorganic semiconductor nanowire due to excellent characteristics of a nano-sized material such as high mobility, high integration, and the like is actively being made.

The inorganic semiconductor nanowire has representatively been manufactured into a semiconductor by using a chemical vapor deposition (CVD) method to raise a nanowire on a substrate. A transistor having high charge mobility may be manufacture by using a silicon nanowire or a zinc oxide (ZnO) nanowire raised in the chemical vapor deposition (CVD) method.

However, an anodic aluminum oxide template method, a hydrothermal synthesis method, an electroless etching method, and the like, as well as the conventional chemical vapor deposition (CVD) method, have the following problems.

1) In order to manufacture an electronic device including an inorganic semiconductor nanowire as an active layer, the nanowire should be horizontally laid but vertically grown in the conventional methods, and thus a separate process of separating the nanowire from a substrate and dispersing it is required. However, since the nanowire is irregularly spread, it is impossible to control the orientation and the position of each nanowire, and thus to manufacture a nanowire device array having a highly integrated large area.

2) In order to manufacture a device including a nanowire horizontally laid on a substrate, an electrode should be deposited, but the conventional methods need very expensive equipment called an E-beam evaporator to deposit the electrode, since the nanowire is very short (usually less than or equal to tens of micrometers) and irregular, and is also irregularly orientated on the substrate, and thus requires a long process time and is expensive. In addition, these methods are not appropriate for mass production of an electronic device including a nanowire, since a position for depositing the electrode about each nanowire is directly designated.

Accordingly, a method of manufacturing an electronic device including an inorganic semiconductor nanowire by precisely adjusting position and direction of the inorganic semiconductor nanowire as well as raising the inorganic semiconductor nanowire up to a desired length, and thus reducing its manufacture time and being suitable for a mass production, is required.

### SUMMARY OF THE INVENTION

### Technical Object

One embodiment of the present invention provides a method of manufacturing an oxide semiconductor wire pattern capable of aligning an oxide semiconductor wire up to a desired length and a desired number in a desired direction at a high rate with high precision, an oxide semiconductor wire pattern manufactured using the method, and an electronic device including the oxide semiconductor wire pattern.

### Technical Solving Method

One embodiment provides a method for forming an aligned oxide semiconductor wire pattern including:

dissolving an oxide semiconductor precursor and an organic polymer in distilled water or an organic solvent to provide a composite solution of an oxide semiconductor precursor/organic polymer;

continuously discharging the composite solution of the oxide semiconductor precursor/organic polymer in a vertical upper direction from a substrate to align an oxide semiconductor precursor/organic polymer composite wire on the substrate; and

heating the oxide semiconductor precursor/organic polymer composite wire to remove the organic polymer and converting the oxide semiconductor precursor into an oxide semiconductor to form an aligned oxide semiconductor wire pattern.

The discharging of the oxide semiconductor precursor/organic polymer composite solution may include discharging the composite solution at a position 10 μm to 20 mm apart from the substrate in a vertical upper direction.

The heating of the oxide semiconductor precursor/organic polymer composite wire may be performed at a temperature ranging from 100° C. to 900° C. for 1 minute to 24 hours.

The oxide semiconductor precursor/organic polymer composite wire may have a circular, oval, or semicircle cross-section.

The alignment of the oxide semiconductor precursor/organic polymer composite wire may be performed by using an electric field auxiliary robotic nozzle printer.

The electric field auxiliary robotic nozzle printer may include: i) a solution storage unit receiving an oxide semiconductor precursor/organic polymer composite solution; ii) a nozzle unit configured to discharge the solution supplied from the solution storage unit; iii) a voltage applying unit configured to apply a high voltage to the nozzle; iv) a collector fixing the substrate; v) a robot stage configured to transfer the collector in a horizontal direction; vi) a micro-distance controller configured to transfer the collector in a vertical direction; and vii) a base plate supporting the collector.

The alignment of the oxide semiconductor precursor/organic polymer composite wire may include: i) supplying the oxide semiconductor precursor/organic polymer composite solution to the solution storage unit of the electric field auxiliary robotic nozzle printer; and ii) applying a high voltage to the nozzle through the voltage applying unit of the electric field auxiliary robotic nozzle printer to discharge the oxide semiconductor precursor/organic polymer composite solution from the nozzle,

wherein a continuously connected solidified oxide semiconductor precursor/organic polymer composite wire is aligned on the substrate by moving the substrate while the oxide semiconductor precursor/organic polymer composite solution is discharged in a vertical upper direction from the substrate, when the oxide semiconductor precursor/organic polymer composite solution forms a Taylor cone at the end of the nozzle.

A vertical distance between the collector and the nozzle may be 10 μm to 20 mm.

The substrate may be selected from the group consisting of an insulation material, a metal material, a carbon material, and a composite material of a conductor, and an insulation layer.

The oxide semiconductor precursor may be selected from the group consisting of a zinc oxide precursor, an indium oxide precursor, a tin oxide precursor, a gallium oxide precursor, a tungsten oxide precursor, an aluminum oxide precursor, a titanium oxide precursor, a vanadium oxide precursor, a molybdenum oxide precursor, a copper oxide precursor, a nickel oxide precursor, an iron oxide precursor, a chromium oxide precursor, a bismuth oxide precursor, and a combination thereof.

The zinc oxide precursor may be selected from the group consisting of zinc hydroxide (Zn(OH)₂), zinc acetate (Zn(CH₃COO)₂), zinc acetate hydrate (Zn(CH₃(COO)₂.nH₂O), diethyl zinc (Zn(CH₃CH₂)₂), zinc nitrate (Zn(NO₃)₂), zinc nitrate hydrate (Zn(NO₃)₂.nH₂O), zinc carbonate (Zn(CO₃)), zinc acetyl acetonate (Zn(CH₃COCHCOCH₃)₂), zinc acetyl acetonate hydrate (Zn(CH₃COCHCOCH₃)₂.nH₂O), and a combination thereof, but is not limited thereto.

The indium oxide precursor may be selected from the group consisting of indium nitrate hydrate (In(NO₃)₃.nH₂O), indium acetate (In(CH₃COO)₂), indium acetate hydrate (In(CH₃(COO)₂.nH₂O), indium chloride (InCl, InCl₂, InCl₃), indium nitrate (In(NO₃)₃), indium nitrate hydrate (In(NO₃)₃.nH₂O), indium acetyl acetonate (In(CH₃COCHCOCH₃)₂), indium acetyl acetonate hydrate (In(CH₃COCHCOCH₃)₂.nH₂O), and a combination thereof, but is not limited thereto.

The tin oxide precursor may be selected from the group consisting of tin acetate (Sn(CH₃COO)₂), tin acetate hydrate (Sn(CH₃(COO)₂.nH₂O), tin chloride(SnCl₂, SnCl₄), tin chloride hydrate (SnClₙ.nH₂O), tin acetyl acetonate (Sn(CH₃COCHCOCH₃)₂), tin acetyl acetonate hydrate (Sn(CH₃COCHCOCH₃)₂.nH₂O), and a combination thereof, but is not limited thereto.

The gallium oxide precursor may be selected from the group consisting of gallium nitrate (Ga(NO₃)₃), gallium nitrate hydrate (Ga(NO₃)₃.nH₂O), gallium acetyl acetonate (Ga(CH₃COCHCOCH₃)₃), gallium acetyl acetonate hydrate (Ga(CH₃COCHCOCH₃)₃.nH₂O), gallium chloride (Ga₂Cl₄, GaCl₃), and a combination thereof, but is not limited thereto.

The tungsten oxide precursor may be selected from the group consisting of tungsten carbide (WC), a tungstic acid powder (H₂WO₄), tungsten chloride (WCl₄ and WCl₆), tungsten isopropoxide (W(OCH(CH₃)₂)₆), sodium tungstate (Na₂WO₄), sodium tungstate hydrate (Na₂WO₄.nH₂O), ammonium tungstate ((NH₄)₆H₂W₁₂O₄₀), ammonium tungstate hydrate ((NH₄)₆H₂W₁₂O₄₀.nH₂O), tungsten ethoxide (W(OC₂H₅)₆), and a combination thereof, but is not limited thereto.

The aluminum oxide precursor may be selected from the group consisting of aluminum chloride (AlCl₃), aluminum nitrate (Al(NO₃)₃), aluminum nitrate hydrate (Al(NO₃)₃.nH₂O), aluminum butoxide (Al(C₂H₅CH(CH₃)O)), and a combination thereof, but is not limited thereto.

The titanium oxide precursor may be selected from the group consisting of titanium isopropoxide (Ti(OCH(CH₃)₂)₄), titanium chloride (TiCl₄), titanium ethoxide (Ti(OC₂H₅)₄), titanium butoxide (Ti(OC₄H₉)₄), and a combination thereof, but is not limited thereto.

The vanadium oxide precursor may be selected from the group consisting of vanadium isopropoxide (VO(OC₃H₇)₃), ammonium vanadate (NH₄VO₃), vanadium acetylacetonate (V(CH₃COCHCOCH₃)₃), vanadium acetylacetonate hydrate (V(CH₃COCHCOCH₃)₃.nH₂O), and a combination thereof, but is not limited thereto.

The molybdenum oxide precursor may be selected from the group consisting of molybdenum isopropoxide (Mo(OC₃H₇)₅), molybdenum chloride isopropoxide (MoCl₃(OC₃H₇)₂), ammonium molybdate ((NH₄)₂MoO₄), ammonium molybdatehydrate ((NH₄)₂MoO₄.nH₂O), and a combination thereof, but is not limited thereto.

The copper oxide precursor may be selected from the group consisting of copper chloride (CuCl, CuCl₂), copper chloride hydrate (CuCl₂.nH₂O), copper acetate (Cu(CO₂CH₃), Cu(CO₂CH₃)₂), copper acetate hydrate (Cu(CO₂CH₃)₂.nH₂O), copper acetyl acetonate (Cu(C₅H₇O₂)₂), copper nitrate (Cu(NO₃)₂), copper nitrate hydrate (Cu(NO₃)₂.nH₂O), copper bromide (CuBr, CuBr₂), copper carbonate (CuCO₃Cu(OH)₂), copper sulfide (Cu₂S, CuS), copper phthalocyanine (C₃₂H₁₆N₈Cu), copper trifluoroacetate (Cu(CO₂CF₃)₂), copper isobutyrate (C₈H₁₄CuO₄), copper ethyl acetoacetate (C₁₂H₁₈CuO₆), copper2-ethylhexanoate ([CH₃(CH₂)₃CH(C₂H₅)CO₂]₂Cu), copper fluoride (CuF₂), copper formate hydrate ((HCO₂)₂Cu.H₂O), copper gluconate (C₁₂H₂₂CuO₁₄), copper hexafluoroacetylacetonate (Cu(C₅HF₆O₂)₂), copper hexafluoroacetylacetonate hydrate (Cu(C₅HF₆O₂)₂.H₂O), copper methoxide (Cu(OCH₃)₂), copper neodecanoate (C₁₀H₁₉O₂Cu), copper perchlorate hydrate (Cu(CLO₄)₂.6H₂O), copper sulfate (CuSO₄), copper sulfate hydrate (CuSO₄.H₂O), copper tartrate hydrate ([CH(OH)CO₂]₂Cu.H₂O), copper trifluoroacetylacetonate (Cu(C₅H₄F₃O₂)₂), copper trifluoromethane sulfonate ((CF₃SO₃)₂Cu), tetraamine copper sulfatehydrate (Cu(NH₃)₄SO₄.H₂O), and a combination thereof, but is not limited thereto.

The nickel oxide precursor may be selected from the group consisting of nickel chloride (NiCl₂), nickel chloride hydrate (NiCl₂.nH₂O), nickel acetate hydrate (Ni(OCOCH₃)₂.4H₂O), nickel nitrate hydrate (Ni(NO₃)₂.6H₂O), nickel acetylacetonate (Ni(C₅H₇O₂)₂), nickel hydroxide (NiOH)₂, nickel phthalocyanine (C₃₂H₁₆N₈Ni), nickel carbonate hydrate (NiCO₃.2Ni(OH)₂.nH₂O), and a combination thereof, but is not limited thereto.

The iron oxide precursor may be selected from the group consisting of iron acetate (Fe(CO₂CH₃)₂), iron chloride (FeCl₂, FeCl₃), iron chloride hydrate (FeCl₃.nH₂O), iron acetylacetonate (Fe(C₅H₇O₂)₃), iron nitrate hydrate (Fe(NO₃)₃.9H₂O), iron phthalocyanine (C₃₂H₁₆FeN₈), iron oxalate hydrate (Fe(C₂O₄).nH₂O, Fe₂(C₂O₄)₃.6H₂O), and a combination thereof, but is not limited thereto.

The chromium oxide precursor may be selected from the group consisting of chromium chloride (CrCl₂, CrCl₃), chromium chloride hydrate (CrCl₃.nH₂O), chromium carbide (Cr₃C₂), chromium acetylacetonate (Cr(C₅H₇O₂)₃), chromium nitrate hydrate (Cr(NO₃)₃.H₂O), chromium hydroxide acetate (CH₃CO₂)₇Cr₃(OH)₂, chromium acetate hydrate ([(CH₃CO₂)₂Cr.H₂O]₂), and a combination thereof, but is not limited thereto.

The bismuth oxide precursor may be selected from the group consisting of bismuth chloride (BiCl₃), bismuth nitrate hydrate (Bi(NO₃)₃.nH₂O), bismuth acetate ((CH₃CO₂)₃Bi), bismuth carbonate ((BiO)₂CO₃), and a combination thereof, but is not limited thereto.

The organic polymer may be selected from the group consisting of polyvinyl alcohol (PVA), polyethylene oxide (PEO), polystyrene (PS), polycaprolactone (PCL), polyacrylonitrile (PAN), poly(methyl methacrylate) (PMMA), polyimide, poly(vinylidene fluoride) (PVDF), polyaniline (PANI), polyvinylchloride(PVC), nylon, poly(acrylic acid), poly(chloro styrene), poly(dimethyl siloxane), poly(ether imide), poly(ether sulfone), poly(alkyl acrylate), poly(ethyl acrylate), poly(ethyl vinyl acetate), poly(ethyl-co-vinyl acetate), poly(ethylene terephthalate), poly(lactic acid-co-glycolic acid), a poly(methacrylate) salt, poly(methyl styrene), a poly(styrene sulfonate) salt, poly(styrene sulfonyl fluoride), poly(styrene-co-acrylonitrile), poly(styrene-co-butadiene), poly(styrene-co-divinyl benzene), poly(vinyl acetate), polylactide, poly(vinyl alcohol), polyacrylamide, polybenzimidazole, polycarbonate, poly(dimethylsiloxane-co-polyethyleneoxide), poly(etheretherketone), polyethylene, polyethyleneimine, polyisoprene, polylactide, polypropylene, polysulfone, polyurethane, poly(vinylpyrrolidone), poly(phenylene vinylene), poly(vinyl carbazole), and a combination thereof, but is not limited thereto.

The organic solvent may be selected from the group consisting of dichloroethylene, trichloroethylene, chloroform, chlorobenzene, dichlorobenzene, dichloromethane, styrene, dimethylformamide, dimethylsulfoxide, tetrahydrofuran, xylene, toluene, cyclohexene, 2-methoxyethanol, ethanolamine, acetonitrile, butylalcohol, isopropylalcohol, ethanol, methanol, and acetone, and a combination thereof, but is not limited thereto.

A diameter of the oxide semiconductor wire may be 10 nm to 1000 μm, and more specifically 50 nm to 5 μm.

The oxide semiconductor wire may be raised to have a desired length of as short as greater than or equal to 10 nm to as long as greater than or equal to thousands of km, for example, from 1 μm to 1 km. The length of the wire may be determined by capacity of the solution continuously supplied to a nozzle.

The aligned oxide semiconductor wire pattern may be horizontally aligned.

Another embodiment provides an electronic device including the aligned oxide semiconductor wire formed by the method according to the embodiment.

The electronic device may be a pressure sensor including the aligned oxide semiconductor wire.

The electronic device may be a photosensor including the aligned oxide semiconductor wire.

The electronic device may be a CMOS (Complementary Metal-Oxide-Semiconductor) sensor including the aligned oxide semiconductor wire.

The electronic device may be a gas sensor including the aligned oxide semiconductor wire.

The electronic device may be a solar cell including the aligned oxide semiconductor wire.

The electronic device may be a field effect transistor including the aligned oxide semiconductor wire.

The electronic device may be a light emitting transistor including the aligned oxide semiconductor wire.

The electronic device may be a laser device including the aligned oxide semiconductor wire.

The electronic device may be a memory including the aligned oxide semiconductor wire.

The electronic device may be a piezoelectric device including the aligned oxide semiconductor wire.

The electronic device may be a battery including the aligned oxide semiconductor wire.

The electronic device may be a logic circuit including the aligned oxide semiconductor wire.

The electronic device may be a ring oscillator including the aligned oxide semiconductor wire.

### Advantageous Effect

A method of an aligning oxide semiconductor wire with a desired length, direction, and shape is provided, and thereby various electronic devices may be manufactured by using the oxide semiconductor wire in a speedy and simple method. In particular, an electronic device array having a large area and high performance at a higher rate with more precision may be provided according to the embodiment.

### BRIEF DESCRIPTION OF THE DRAWINGS

FIG. 1 is a flowchart schematically showing a process of manufacturing an oxide semiconductor wire pattern according to one embodiment.

FIG. 2 is a schematic view showing an electric field auxiliary robotic nozzle printer used in the forming method according to one embodiment.

FIGS. 3A and 3B are SEM photographs showing an aligned zinc oxide (ZnO) wire pattern.

FIG. 4 is a graph showing output voltage characteristics of an inverter manufactured by using the aligned zinc oxide (ZnO) and copper oxide (CuO) wire patterns.

FIG. 5 is a flowchart showing a method of manufacturing an oxide semiconductor nanowire field effect transistor having a bottom-gate structure according to an exemplary embodiment.

FIG. 6 is a flowchart showing a method of manufacturing an oxide semiconductor nanowire field effect transistor having a top-gate structure according to an exemplary embodiment.

FIGS. 7A and 7B are SEM photographs showing the zinc oxide (ZnO) nanowire pattern aligned on a source/drain electrode.

FIG. 8 is a photomicrograph showing a substrate having a source electrode and a drain electrode according to Example 12, wherein a metal oxide nanowire pattern is horizontally aligned on the source and drain electrodes.

FIG. 9 shows scanning electron microscope (SEM) photographs of a ZnO nanowire according to Example 13, and specifically, the nanowires before the heat treatment (top left and right) and after the heat treatment (bottom left and right), and the side of the nanowires (left top and bottom) and the cross-sections (right top and bottom) of the nanowires. FIG. 10 is a scanning electron microscope (SEM) photograph showing the aligned ZnO nanowires according to Example 13.

FIG. 11A is a graph showing resistance versus time of a ZnO nanowire gas sensor of Example 13, and FIG. 11B is a graph showing Response (Rg/Ra) versus NO₂ gas concentration of the ZnO nanowire gas sensor.

FIG. 12 shows that different metal oxide (\textcircled{1}-zinc oxide, \textcircled{2}-tin oxide, \textcircled{3}-indium oxide, and \textcircled{4}-tungsten oxide) nanowires are respectively formed on a substrate having a plurality of pairs of a source electrode and a drain electrode according to Example 13.

FIG. 13A is a scanning electron microscope (SEM) photograph showing the ZnO nanowire of Example 13 (top: nanowire before heat treatment, bottom: nanowire after heat treatment), and FIG. 13B is a graph showing resistance versus time of the ZnO nanowire gas sensor of Example 13 regarding C₂H₅OH and NO₂ gases.

FIG. 14A shows scanning electron microscope (SEM) photographs of the SnO₂ nanowire according to Example 13 before the heat treatment (top) and after the heat treatment (bottom), and FIG. 14B shows a graph showing resistance versus time regarding NO₂ gas of a gas sensor including the nanowire, and a graph showing resistance versus time regarding C₂H₅OH gas.

FIG. 15A shows scanning electron microscope (SEM) photographs of the In₂O₃ nanowire according to Example 13 before the heat treatment (top) and after the heat treatment (bottom), and FIG. 15B shows a graph showing resistance versus time regarding C₂H₅OH gas of a gas sensor including the nanowire, and a graph showing resistance versus time regarding NO₂ gas.

### DETAILED DESCRIPTION

Hereinafter, embodiments of the present invention are described in detail. However, these embodiments are exemplary, and do not limit the present invention, and the present invention is defined by the scope of the claims which will be described later.

One embodiment of the present invention provides a method for forming an aligned oxide semiconductor wire pattern.

In the present specification, the “aligned” wire refers to a wire having adjusted positions and directions as needed. In addition, a wire pattern obtained in conventional offset printing, inkjet printing, screen printing, and imprinting methods has a large rectangular cross-section, but a wire pattern according o the present invention has a circular, oval, or semicircular cross-section. Unlike a single crystalline semiconductor nanowire manufactured in a conventional chemical synthesis and growth method and having a length of less than or equal to tens of micrometers, a polycrystalline wire formed of nanograins connected to one another through printing is provided and may have a desired pattern length when a roll-to-roll process is applied thereto.

A method for forming an oxide semiconductor wire pattern includes: dissolving an oxide semiconductor precursor and an organic polymer in distilled water or an organic solvent to provide a composite solution of an oxide semiconductor precursor/organic polymer; continuously discharging the composite solution of the oxide semiconductor precursor/organic polymer in a vertical direction from an upper substrate to align an oxide semiconductor precursor/organic polymer composite wire on the substrate; and heating the oxide semiconductor precursor/organic polymer composite wire to remove the organic polymer and converting the oxide semiconductor precursor into an oxide semiconductor to form an aligned oxide semiconductor wire pattern.

The discharging of the oxide semiconductor precursor/organic polymer composite solution may include discharging the composite solution at a position 10 μm to 20 mm apart from the substrate in a vertical upper direction.

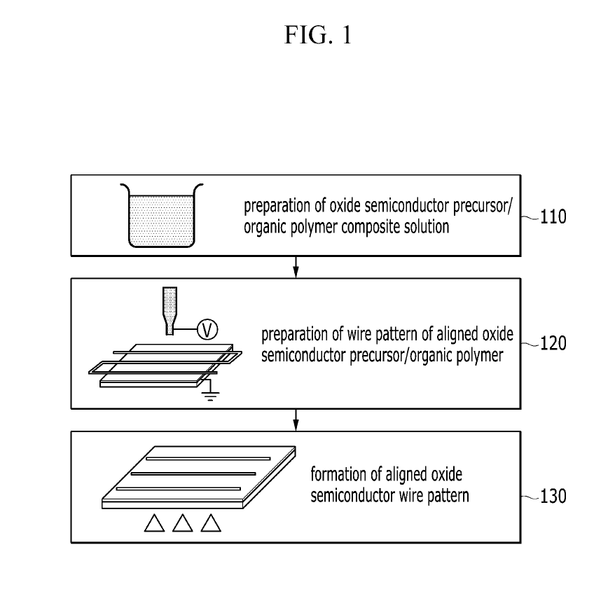

FIG. 1 is a flowchart schematically showing a process of manufacturing an oxide semiconductor wire pattern according to an exemplary embodiment of the present invention, and specifically, providing an oxide semiconductor precursor/organic polymer composite solution (110); continuously discharging the oxide semiconductor precursor/organic polymer composite solution to align an oxide semiconductor precursor/organic polymer composite wire on a substrate (120); and heating the aligned oxide semiconductor precursor/organic polymer composite wire to remove the organic polymer and converting the oxide semiconductor precursor into an oxide semiconductor to form an aligned oxide semiconductor wire pattern (130).

The substrate may be selected from the group consisting of an insulation material, a metal material, a carbon material, and a composite material of a conductor, and an insulation layer. Specifically, examples of the insulation material may include glass, a plastic film, paper, fabric, wood, and the like, examples of the metal material may include copper, aluminum, titanium, gold silver, stainless steel, and the like, examples of the carbon material may include graphene, carbon nanotubes, graphite amorphous carbon, and the like, and examples of the conductor/insulation layer composite material may include a semiconductor wafer substrate, a silicon (Si)/silicon dioxide (SiO₂) substrate, and an aluminum (AD/aluminum oxide (Al₂O₃) substrate.

Because an oxide semiconductor has a bandgap, it has drawn attention as very important electron and photoelectron material. One embodiment of the present invention provides a method of obtaining a pattern by aligning the oxide semiconductor wire.

Specifically, the method of aligning the oxide semiconductor wire is as follows.

First, a solution including an oxide semiconductor precursor and an organic polymer is prepared.

The oxide semiconductor precursor may be selected from the group consisting of a zinc oxide precursor, an indium oxide precursor, a tin oxide precursor, a gallium oxide precursor, a tungsten oxide precursor, an aluminum oxide precursor, a titanium oxide precursor, a vanadium oxide precursor, a molybdenum oxide precursor, a copper oxide precursor, a nickel oxide precursor, an iron oxide precursor, a chromium oxide precursor, a bismuth oxide precursor, and a combination thereof.

The zinc oxide precursor may be selected from the group consisting of zinc hydroxide (Zn(OH)₂), zinc acetate (Zn(CH₃COO)₂), zinc acetate hydrate (Zn(CH₃(COO)₂.nH₂O), diethyl zinc (Zn(CH₃CH₂)₂), zinc nitrate (Zn(NO₃)₂), zinc nitrate hydrate (Zn(NO₃)₂.nH₂O), zinc carbonate (Zn(CO₃)), zinc acetyl acetonate (Zn(CH₃COCHCOCH₃)₂), zinc acetyl acetonate hydrate (Zn(CH₃COCHCOCH₃)₂.nH₂O), and a combination thereof, but is not limited thereto.

The indium oxide precursor may be selected from the group consisting of indium nitrate hydrate(In(NO₃)₃.nH₂O), indium acetate (In(CH₃COO)₂), indium acetate hydrate (In(CH₃(COO)₂.nH₂O), indium chloride (InCl, InCl₂, InCl₃), indium nitrate (In(NO₃)₃), indium nitrate hydrate(In(NO₃)₃.nH₂O), indium acetyl acetonate (In(CH₃COCHCOCH₃)₂), indium acetyl acetonate hydrate (In(CH₃COCHCOCH₃)₂H₂O), and a combination thereof, but is not limited thereto.

The tin oxide precursor may be selected from the group consisting of tin acetate (Sn(CH₃COO)₂), tin acetate hydrate (Sn(CH₃(COO)₂.nH₂O), tin chloride (SnCl₂, SnCl₄), tin chloride hydrate (SnClₙ.nH₂O), tin acetyl acetonate (Sn(CH₃COCHCOCH₃)₂), tin acetyl acetonate hydrate (Sn(CH₃COCHCOCH₃)₂.nH₂O), and a combination thereof, but is not limited thereto.

The gallium oxide precursor may be selected from the group consisting of gallium nitrate (Ga(NO₃)₃), gallium nitrate hydrate (Ga(NO₃)₃H₂O), gallium acetyl acetonate (Ga(CH₃COCHCOCH₃)₃), gallium acetyl acetonate hydrate (Ga(CH₃COCHCOCH₃)₃.nH₂O), gallium chloride (Ga₂Cl₄, GaCl₃), and a combination thereof, but is not limited thereto.

The tungsten oxide precursor may be selected from the group consisting of tungsten carbide (WC), a tungstic acid powder (H₂WO₄), tungsten chloride (WCl₄ and WCl₆), tungsten isopropoxide (W(OCH(CH₃)₂)₆), sodium tungstate (Na₂WO₄), sodium tungstate hydrate (Na₂WO₄.nH₂O), ammonium tungstate ((NH₄)₆H₂W₁₂O₄₀), ammonium tungstate hydrate ((NH₄)₆H₂W₁₂O₄₀.nH₂O), tungsten ethoxide (W(OC₂H₅)₆), and a combination thereof, but is not limited thereto.

The aluminum oxide precursor may be selected from the group consisting of aluminum chloride (AlCl₃), aluminum nitrate (Al(NO₃)₃), aluminum nitrate hydrate (Al(NO₃)₃H₂O), aluminum butoxide (Al(C₂H₅CH(CH₃)O)), and a combination thereof, but is not limited thereto.

The titanium oxide precursor may be selected from the group consisting of titanium isopropoxide (Ti(OCH(CH₃)₂)₄), titanium chloride (TiCl₄), titanium ethoxide (Ti(OC₂H₅)₄), titanium butoxide (Ti(OC₄H₉)₄), and a combination thereof, but is not limited thereto.

The vanadium oxide precursor may be selected from the group consisting of vanadium isopropoxide (VO(OC₃H₇)₃), ammonium vanadate (NH₄VO₃), vanadium acetylacetonate (V(CH₃COCHCOCH₃)₃), vanadium acetylacetonate hydrate (V(CH₃COCHCOCH₃)₃.nH₂O), and a combination thereof, but is not limited thereto.

The molybdenum oxide precursor may be selected from the group consisting of molybdenum isopropoxide (Mo(OC₃H₇)₅), molybdenum chloride isopropoxide (MoCl₃(OC₃H₇)₂), ammonium molybdate ((NH₄)₂MoO₄), ammonium molybdatehydrate ((NH₄)₂MoO₄.nH₂O), and a combination thereof, lo but is not limited thereto.

The copper oxide precursor may be selected from the group consisting of copper chloride (CuCI, CuCl₂), copper chloride hydrate (CuCl₂.nH₂O), copper acetate (Cu(CO₂CH₃), Cu(CO₂CH₃)₂), copper acetate hydrate (Cu(CO₂CH₃)₂.nH₂O), copper acetyl acetonate (Cu(C₅H₇O₂)₂), copper nitrate (Cu(NO₃)₂), copper nitrate hydrate (Cu(NO₃)₂.nH₂O), copper bromide (CuBr, CuBr₂), copper carbonate (CuCO₃Cu(OH)₂), copper sulfide (Cu₂S, CuS), copper phthalocyanine (C₃₂H₁₆N₈Cu), copper trifluoroacetate (Cu(CO₂CF₃)₂), copper isobutyrate (C₈H₁₄CuO₄), copper ethyl acetoacetate (C₁₂H₁₈CuO₆), copper2-ethylhexanoate ([CH₃(CH₂)₃CH(C₂H₅)CO₂]₂Cu), copper fluoride (CuF₂), copper formate hydrate ((HCO₂)₂Cu.H₂O), copper gluconate (C₁₂H₂₂CuO₁₄), copper hexafluoroacetylacetonate (Cu(C₅HF₆O₂)₂), copper hexafluoroacetylacetonate hydrate (Cu(C₅HF₆O₂)₂.H₂O), copper methoxide (Cu(OCH₃)₂), copper neodecanoate (C₁₀H₁₉O₂Cu), copper perchlorate hydrate (Cu(ClO₄)₂.6H₂O), copper sulfate (CuSO₄), copper sulfate hydrate (CuSO₄.H₂O), copper tartrate hydrate ([^{-CH(OH)CO}₂]₂Cu.H₂O), copper trifluoroacetylacetonate (Cu(C₅H₄F₃O₂)₂), copper trifluoromethane sulfonate ((CF₃SO₃)₂Cu), tetraamine copper sulfatehydrate (Cu(NH₃)₄SO₄.H₂O), and a combination thereof, but is not limited thereto.

The nickel oxide precursor may be selected from the group consisting of nickel chloride (NiCl₂), nickel chloride hydrate (NiCl₂.nH₂O), nickel acetate hydrate (Ni(OCOCH₃)₂.4H₂O), nickel nitrate hydrate (Ni(NO₃)₂.6H₂O), nickel acetylacetonate (Ni(C₅H₇O₂)₂), nickel hydroxide (NiOH)₂, nickel phthalocyanine (C₃₂H₁₆N₈Ni), nickel carbonate hydrate (NiCO₃.2Ni(OH)₂.nH₂O), and a lo combination thereof, but is not limited thereto.

The iron oxide precursor may be selected from the group consisting of iron acetate (Fe(CO₂CH₃)₂), iron chloride (FeCl₂, FeCl₃), iron chloride hydrate (FeCl₃.nH₂O), iron acetylacetonate (Fe(C₅H₇O₂)₃), iron nitrate hydrate (Fe(NO₃)₃.9H₂O), iron phthalocyanine (C₃₂H₁₆FeN₈), iron oxalate hydrate (Fe(C₂O₄).nH₂O, Fe₂(C₂O₄)₃.6H₂O), and a combination thereof, but is not limited thereto.

The chromium oxide precursor may be selected from the group consisting of chromium chloride (CrCl₂, CrCl₃), chromium chloride hydrate (CrCl₃.nH₂O), chromium carbide (Cr₃C₂), chromium acetylacetonate (Cr (C₅H₇O₂)₃), chromium nitrate hydrate (Cr(NO₃)₃.nH₂O), chromium hydroxide acetate (CH₃CO₂)₇Cr₃(OH)₂, chromium acetate hydrate ([(CH₃CO₂)₂CR.H₂O]₂), and a combination thereof, but is not limited thereto.

The bismuth oxide precursor may be selected from the group consisting of bismuth chloride (BiCl₃), bismuth nitrate hydrate (Bi(NO₃)₃.nH₂O), bismuth acetate ((CH₃CO₂)₃Bi), bismuth carbonate ((BiO)₂CO₃), and a combination thereof, but is not limited thereto.

In an exemplary embodiment, the oxide semiconductor made of the oxide semiconductor precursor may include at least one selected from the group consisting of ZnO, SnO₂, TiO₂, WO₃, In₂O₃, CuO, NiO, Fe₂O₃, MoO₃, V2O5, Cr₂O₃, Bi₂O₃, and Al₂O₃, but is not limited thereto.

The organic polymer may be selected from the group consisting of polyvinyl alcohol (PVA), polyethylene oxide (PEO), polystyrene (PS), polycarprolactone (PCL), polyacrylonitrile (PAN), poly(methyl methacrylate) (PMMA), polyimide, poly(vinylidene fluoride) (PVDF), polyaniline (PANI), polyvinylchloride (PVC), nylon, poly(acrylic acid), poly(chloro styrene), poly(dimethyl siloxane), poly(ether imide), poly(ether sulfone), poly(alkyl acrylate), poly(ethyl acrylate), poly(ethyl vinyl acetate), poly(ethyl-co-vinyl acetate), poly(ethylene terephthalate), poly(lactic acid-co-glycolic acid), a poly(methacrylate) salt, poly(methyl styrene), a poly(styrene sulfonate) salt, poly(styrene sulfonyl fluoride), poly(styrene-co-acrylonitrile), poly(styrene-co-butadiene), poly(styrene-co-divinyl benzene), poly(vinyl acetate), polylactide, poly(vinyl alcohol), polyacrylamide, polybenzimidazole, polycarbonate, poly(dimethylsiloxane-co-polyethylene oxide), poly(etheretherketone), polyethylene, polyethyleimine, polyisoprene, polylactide, polypropylene, polysulfone, polyurethane, poly(vinylpyrrolidone), poly(phenylene vinylene), poly(vinyl carbazole), and a combination thereof, but is not limited thereto.

During preparation of the solution, water or an organic solvent may be used as a solvent, and the organic solvent may be selected from the group consisting of dichloroethylene, trichloroethylene or chloroform, chlorobenzene, dichlorobenzene, dichloromethane, styrene, dimethylformamide, dimethylsulfoxide, tetrahydrofuran, xylene, toluene, cyclohexene, 2-methoxyethanol, ethanolamine, acetonitrile, butylalcohol, isopropyl alcohol, ethanol, methanol, and acetone, and a combination thereof, but is not limited thereto.

The oxide semiconductor precursor and an organic polymer may be mixed in a weight ratio of 10:90 to 97:3. More specifically, the weight ratio may be in a range of 70:30 to 90:10. When the oxide semiconductor precursor and the organic polymer are mixed within the ratio range, a finally-obtained oxide semiconductor wire is not broken but has a uniform diameter. Since the organic polymer is decomposed by a heat treatment, when the organic polymer is included in an amount of greater than 90 wt %, the amount of the oxide semiconductor left after the heat treatment is short, and thus a wire may not be uniform and may be broken. In addition, when the organic polymer is included in an amount of less than 3 wt %, an oxide semiconductor precursor-organic polymer solution has so low viscosity that an oxide semiconductor precursor/organic polymer composite wire and pattern may not be properly formed by an electric field auxiliary robotic nozzle printer. Accordingly, a ratio between the oxide semiconductor precursor and the organic polymer may be adjusted to control the diameter of an oxide semiconductor wire.

The oxide semiconductor precursor and organic polymer solution may have a concentration ranging from 1 to 30 wt %. When the oxide semiconductor precursor and the organic polymer are mixed within the ratio range and have a concentration within the range, the solution has so sufficient viscosity that a wire pattern may be formed through an electric field auxiliary robotic nozzle printer. When the oxide semiconductor precursor/organic polymer solution has a concentration of less than 1 wt % of a solute relative to a solvent, the solution has so low viscosity so as to form a drop rather than a wire. In addition, when the oxide semiconductor precursor/organic polymer solution have a concentration of greater than or equal to about 30 wt %, the solution has too high viscosity to be appropriately discharged through an electric field auxiliary robotic nozzle printer.

The prepared oxide semiconductor precursor/organic polymer composite solution may be discharged at a position 10 μm to 20 mm apart from the substrate in a vertical upper direction to align an oxide semiconductor precursor/organic polymer composite wire.

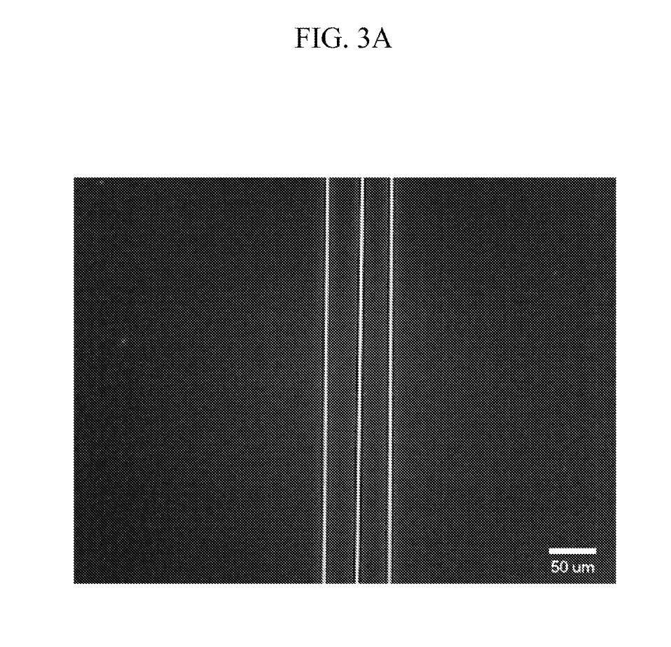

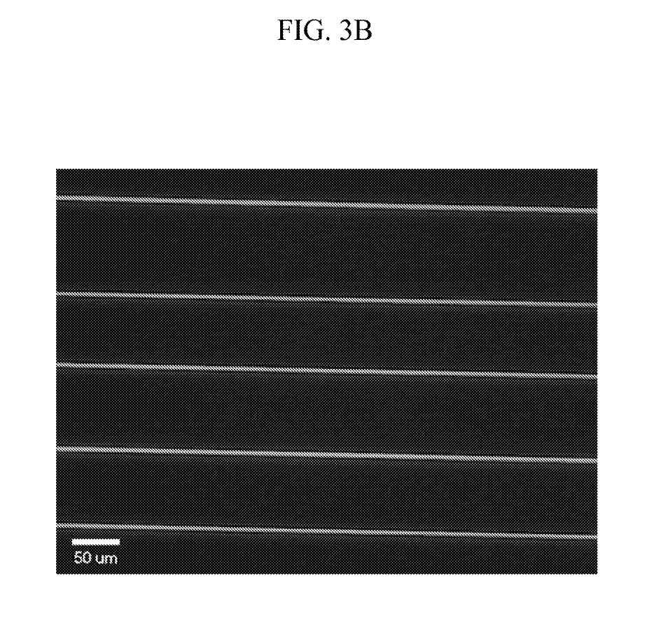

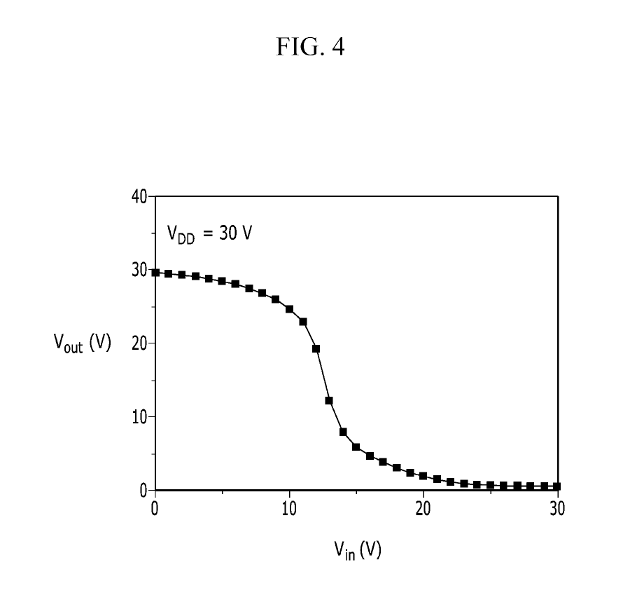

The farther the oxide semiconductor precursor/organic polymer composite solution is dripped from the substrate, the faster the oxide semiconductor precursor/organic polymer composite wire is horizontally aligned, and thus the more the wire may be bent. Accordingly, the wire is disturbed and may not be aligned in a desired direction or in a horizontal direction. However, the present invention may suppress a wire from being bent and align the wire in a desired direction by discharging the oxide semiconductor precursor/organic polymer composite solution in a vertical upper direction 10 μm to 20 mm apart from the substrate, and specifically, 1 mm to 5 mm. FIGS. 3A and 3B are SEM photographs showing a zinc oxide nanowire formed on a substrate, and the wire turns out to be aligned in a horizontal direction.

The alignment of the oxide semiconductor precursor/organic polymer composite wire may be performed by using an electric field auxiliary robotic nozzle printer. The electric field auxiliary robotic nozzle printer may include: i) a solution storage unit receiving an oxide semiconductor precursor/organic polymer composite solution; ii) a nozzle unit configured to discharge the solution supplied from the solution storage unit; iii) a voltage applying unit configured to apply a high voltage to the nozzle; iv) a collector fixing the substrate; v) a robot stage configured to transfer the collector in a horizontal direction; vi) a micro-distance controller configured to transfer the collector in a vertical direction; and vii) a base plate configured to support the collector from the lower side of the collector.

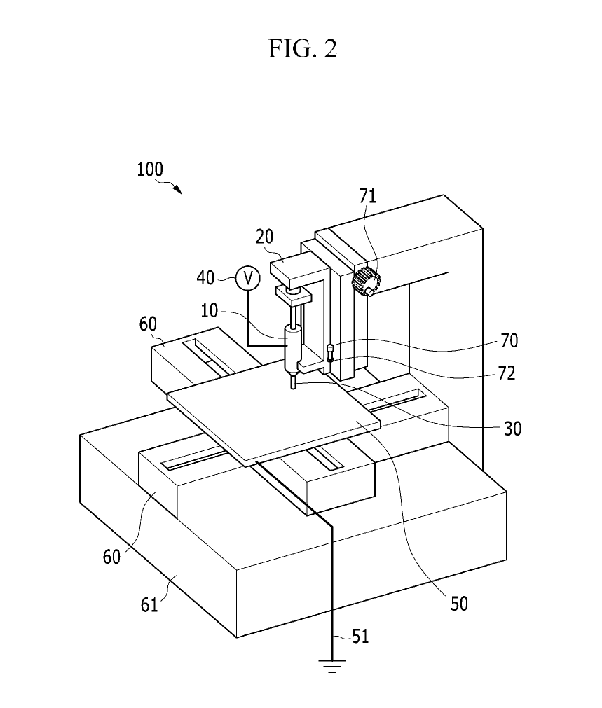

FIG. 2 is a schematic view showing an electric field auxiliary robotic nozzle printer 100. Specifically, the electric field auxiliary robotic nozzle printer 100 includes a solution storage unit 10, a discharge controller 20, a nozzle 30, a voltage applying unit 40, a collector 50, a robot stage 60, base plate 61, a micro-distance controller 70.

The solution storage unit 10 stores an oxide semiconductor precursor/organic polymer composite solution, and supplies it to the nozzle 30 so that the solution can be discharged through the nozzle. The solution storage unit 101 may have a form of a syringe. The solution storage unit 10 may be made by using plastic, glass, or stainless steel, but is not limited thereto. The solution storage unit 10 has a capacity volume in the range of about 1 μl to about 5000 ml. Preferably, the capacity of the solution storage unit may be in the range of about 10 μl to about 50 ml. When the solution storage unit 10 is made of stainless steel, a gas injector (not shown) for injecting gas into the solution storage unit 10 is provided, thus enabling the discharge of the solution to the outside of the solution storage unit by using gas pressure. Meanwhile, the solution storage unit 10 may be formed in plural in order to form an oxide semiconductor wire having a core shell structure.

The discharge controller 20 serves to apply a pressure on an oxide semiconductor precursor/organic polymer composite solution in the solution storage unit 10 to discharge the oxide semiconductor precursor/organic polymer composite solution at a predetermined rate through the nozzle 30. The discharge controller 20 may be a pump or a gas pressure controller. The discharge controller 20 can control the rate of discharge of the solution in the range of about 1 nl/min to about 50 ml/min. When a plurality of solution storage units 10 are used, a separate discharge controller 20 may be provided in each solution storage unit 10 so that each solution storage unit 10 can operate independently. When the solution storage unit 10 is made of stainless steel, a gas pressure controller (not shown) may be used as a discharge controller 20.

The nozzle 30 is configured to discharge the oxide semiconductor precursor/organic polymer composite solution received from the solution storage unit 10, and the solution being discharged can form droplets at the terminal end of the nozzle 30.

The nozzle 30 may have a diameter in the range of about 10 nm to about 1.5 mm, and more preferably 10 μm to 500 μm, but is not limited thereto.

The nozzle 30 may be a single nozzle, a dual-concentric nozzle, or a triple-concentric nozzle. When an oxide semiconductor wire having a core shell structure is formed, two or more different kinds of oxide semiconductor precursor/organic polymer composite solutions may be discharged by using a dual-concentric nozzle or a triple-concentric nozzle. In this case, two or three solution storage units 10 may be connected to the dual-concentric nozzle or the triple-concentric nozzle.

The voltage applying unit 40 is configured to apply a high voltage to the nozzle 30, and it may include a high voltage generating unit. The voltage applying unit 40 may be electrically connected to the nozzles 30, for example, through the solution storage unit 10. The voltage generating unit 40 may apply voltage in the range of about 0.1 kV to about 30 kV, but is not limited thereto. An electric field is present between the nozzle 30 to which the high voltage is applied by the voltage applying unit 40, and the grounded collector 50. Droplets formed at the terminal ends of the nozzle 30 form Taylor cones by the electric field, and wires are continuously formed from the terminal ends.

The collector 50 is a part to which wires formed from the solution discharged from the nozzle 30 are attached. The collector 50 has a flat shape, and is movable on a horizontal plane by the robot stage 60. The collector 50 is configured to be grounded so that it can have a grounding property relative to the high voltage applied to the nozzle 30. Reference numeral 51 indicates that the collector 50 is grounded. The collector 50 can be made of a conductive material, for example, a metal, and have flatness in the range of 0.5 μm to 10 μm (‘flatness’ refers to the maximum error value from a perfect horizontal surface when the flatness of a surface with perfect flatness is ‘0’).

The robot stage 60 is configured to transport the collector 50. The robot stage 60, configured to be driven by a servo motor, can move at a precise velocity. The robot stage 60 can be controlled, for example, to move in two different directions of x axis and y axis directions on a horizontal plane. The robot stage 60 may move at intervals in the range of 10 nm or greater and 100 cm or less, for example, in the range of 10 μm or greater and 20 cm or less. The moving speed of the robot stage 60 can be controlled in the range of 1 mm/min to 60,000 mm/min. The robot stage 60 is installed on the base plate 61, and the base plate 61 can have flatness in the range of 0.1 μm to 5 μm. The lo distance between the nozzle 30 and the collector 50 can be controlled to be a regular interval by the flatness of the base plate 61. The base plate 61 can provide precise control over the oxide semiconductor precursor/organic polymer composite wire patterns by preventing vibrations generated by the operation of the robot stage 60.

The micro-distance controller 70 controls the distance between the nozzle 30 and the collector 50. The distance between the nozzle 30 and the collector 50 can be controlled by vertically transporting the solution storage unit 10 and the nozzle 30 via the micro-distance controller 70.

The micro-distance controller 70 may consist of a jog 71 and a micrometer 72. The jog 71 is used for coarse adjustment of a distance in the range of from a few millimeters to a few centimeters, whereas the micrometer 72 is used for fine adjustment of a distance in the range of about 10 μm or longer. First, nozzle 30 is brought near to the collector 50 by using the jog 71, and then the distance between the nozzle 30 and the collector 50 is precisely adjusted by the micrometer 72. The distance between the nozzle 30 and the collector 50 can be controlled in the range of about 10 μm to about 20 mm.

The three-dimensional path of nanofibers being spun out of the nozzles in electrospinning may be calculated by the following equations (D. H. Reneker, A. L. Yarin, H. Fong, S. Koombhongse, “Bending instability of electrically charged liquid jets of polymer solutions in electrospinning” J. Appl. Phys., 87, 9, 4531-4546 (2000)). As shown in the following Equations 1a and 1b, the greater the distance between the nozzle and the collector, the greater the perturbation of the wire.

$$\begin{matrix}x = {10}^{- 3} L cos ( {{}^{2 π}}_{λ} z ) \frac{h - z}{h} & Equation ( 1 a ) \\ y = {10}^{- 3} L sin ( {{}^{2 π}}_{λ} z ) \frac{h - z}{h} & Equation ( 1 b )\end{matrix}$$

In the equations, x and y respectively represent the positions in the x axis and y axis directions on a flat plane, L is a constant for a length scale, A is a perturbation wavelength, z is a vertical position of a wire relative to a collector (z=0), and h is the distance between the nozzles and the collector. From the Equations 1a and 1b, it is noted that, for the same z value, the greater the distance h between the nozzles and the collector, the greater the values of x and y, which represent the perturbation of the wire.

For example, the collector 50, which is parallel to the horizontal x-y plane, can move on the x-y plane by the robot stage 60, and the distance between the nozzle 30 and the collector 50 can be adjusted along the direction of the z axis by the micro-distance controller 70.

In an embodiment of the present invention, an electric field aided robotic nozzle printer 100 can sufficiently reduce the distance between the nozzle 30 and the collector 50 within a range of ten to a few tens of micrometers, thereby causing the wires to fall onto the collector 50 before they are perturbed. Accordingly, the precise wire patterns can be formed by the movement of the collector 50.

The formation of the wire patterns by the movement of the collector 50 rather than by the movement of the nozzles can reduce perturbation of the wire patterns, thereby enabling the formation of more precise wire patterns.

Meanwhile, the electric field aided robotic nozzle printer 100 can be installed within a housing. The housing can be made of a transparent material. The housing is sealable, and a gas can be injected into the housing through a gas injection inlet (not shown). The gas to be injected into the housing includes nitrogen, dry air, and the like, and the injected gas helps to maintain an oxide semiconductor precursor/organic polymer composite solution which is readily oxidized in the presence of moisture to be stable. Furthermore, the housing may be provided with a ventilator and a lamp. The ventilator is configured to control the vapor pressure in the housing, thereby controlling the evaporation rate of the solvent at the time of forming a wire. In robotic nozzle printing requiring fast evaporation of a solvent, the evaporation of the solvent can be aided by adjusting the speed of the ventilator. The evaporation rate of the solvent may influence the shape and electrical properties of the oxide semiconductor wire. When the evaporation rate of the solvent is too fast, it may cause the solution to dry at the nozzle ends before the oxide semiconductor wires are formed, thus clogging the nozzles. In contrast, when the evaporation rate of the solvent is too slow, it prevents formation of the oxide semiconductor precursor/organic polymer composite wires, and they may be placed in the collector in a liquid state. The oxide semiconductor precursor/organic polymer composite solution in a liquid state cannot be used in the manufacture of devices because it does not have characteristic electrical properties of a wire. As such, the evaporation rate of the solvent has an impact on the formation of a wire, and thus the ventilator can play an important role in the formation of a wire.

Specifically, the alignment of the oxide semiconductor precursor/organic polymer composite wire with the electric field auxiliary robotic nozzle printer 100 includes: i) supplying the solution storage unit with the oxide semiconductor precursor/organic polymer composite solution; and ii) applying a high voltage to the nozzle through the voltage applying unit of the electric field auxiliary robotic nozzle printer to discharge the oxide semiconductor precursor/organic polymer composite solution from the nozzle and transferring a collector having the substrate in a horizontal direction, while the oxide semiconductor precursor/organic polymer composite solution is discharged from the nozzle.

According to one embodiment of the present invention, when a solution including an oxide semiconductor precursor and an organic polymer is put in a syringe 10 and discharged from a nozzle 30 by a syringe pump 20, a droplet is formed at the end of the nozzle 30. When a voltage ranging from about 0.1 kV to about 30 kV is applied to the nozzle 30 by using a high voltage generating unit 40, a Taylor cone is formed at the end of the nozzle by an electrostatic force between a charge formed in a droplet and a collector 50, and the droplet is not dropped or scattered but is dragged in an electric field direction as a fiber shape (or a wire shape) having a round cross-section, while a solvent is evaporated therefrom, and then a long-connected wire in a solid state is stuck to the substrate on the collector.

Herein, as the droplet is stretched, an oxide semiconductor precursor/organic polymer composite wire having a longer length in one direction than in different directions may be formed. This oxide semiconductor precursor/organic polymer composite wire may have a diameter ranging from tens of nanometers to micrometers by adjusting the applied voltage and the nozzle size.

The oxide semiconductor precursor/organic polymer composite wire from an electrically-charged material discharged from the nozzle 30 may be aligned on the substrate on the collector 50. Herein, the oxide semiconductor precursor/organic polymer composite wire is not tangled but is separately formed on the substrate on the collector 50 by adjusting a distance between the nozzle 30 and the collector 50 to be in a range of 10 μm to 20 mm. The distance between the nozzle 30 and the collector 50 may be controlled by using a micro-distance controller 70.

In this way, the micro-distance controller 70 and a micro-controller 72 may be used to minutely move the collector 50 to form the oxide semiconductor precursor/organic polymer composite wire in a desired direction of as many as desired on the substrate.

Herein, the oxide semiconductor precursor/organic polymer composite wire may be horizontally aligned. Accordingly, the oxide semiconductor precursor/organic composite wire pattern may be horizontally aligned.

The oxide semiconductor precursor/organic polymer composite wire aligned in a desired position of as many as desired may be heated at a temperature ranging from 100° C. to 900° C. for 1 minute to 24 hours to form an aligned oxide semiconductor wire pattern. Specifically, the heat treatment may be performed at 300° C. to 900° C. for 1 hour to 15 hours, and more specifically, at 400° C. to 800° C. for 3 hours to 10 hours. Herein, a uniformly-sized oxide semiconductor crystal is formed and thus charge mobility is improved. The heating is performed by using equipment providing uniform heating of the oxide semiconductor precursor/organic polymer composite wire such as a furnace, a vacuum hot-plate, rapid thermal annealing equipment, a CVD (chemical vapor deposition) chamber, or the like.

When the oxide semiconductor precursor/organic polymer composite wire is heated, the organic polymer is decomposed, and the oxide semiconductor precursor is transformed into an oxide semiconductor, obtaining an aligned wire-shaped oxide semiconductor. The oxide semiconductor wire may have a diameter ranging from 10 nm to 1000 μm, and specifically, from 50 nm to 5 μm. The diameter may be adjusted depending on a ratio and a concentration of the oxide semiconductor precursor and the organic polymer. When the oxide semiconductor wire has a diameter of less than 1 μm, the obtained wire may be called a “nanowire”.

The oxide semiconductor wire may be greater than or equal to 10 nm to thousands of km long, and specifically, 1 μm to 1 km long. The obtained oxide semiconductor wire has a small diameter and thus a large surface area. Specifically, an oxide semiconductor wire having a diameter size of visible light or much smaller than visible light may be easily manufactured and thus form a very large surface area.

The oxide semiconductor wire formed according to the present invention has horizontally aligned shapes, and may be usefully applied to various electronic devices, for example a pressure sensor, a photosensor, a CMOS sensor, a gas sensor, a solar cell, a light emitting transistor, a field effect transistor, a laser device, a memory, a piezoelectric device, a battery, a logic circuit, a ring oscillator, and the like.

Accordingly, in another embodiment of the present invention, an electronic device including the aligned oxide semiconductor wire formed by the method according to the embodiment and a manufacturing method thereof are provided.

The electronic device may include a pressure sensor, a photosensor, a CMOS sensor, a gas sensor, a solar cell, a light emitting transistor, a field effect transistor, a laser device, a memory, a piezoelectric device, a battery, a logic circuit, a ring oscillator, or a combination thereof including the aligned oxide semiconductor wire, but is not limited thereto.

For example, the electronic device may be a field effect transistor (FET) including the aligned oxide semiconductor wire formed by the method according to the embodiment.

The field effect transistor (FET) controls a current between a source electrode and a drain electrode by using a principle that a gate is provided for an electron or hole flow by applying a voltage to a gate electrode and generating an electric field in a channel. The field effect transistor is applied to an active matrix-type display as a thin film transistor (TFT), and accordingly, a thin film transistor having high charge mobility and a small threshold voltage change has been required.

A transistor device may have a different structure depending on position of a gate electrode. A bottom gate structure indicates that the gate electrode is positioned toward the substrate, while a top gate structure indicates that the gate electrode is positioned upward. In addition, the transistor device may lo have a different structure depending on positions of source/drain electrodes. When the source/drain electrodes are positioned beneath a semiconductor layer, it is classified as a bottom contact device, while when the source/drain electrode is positioned on the semiconductor layer, it is classified as a top contact device. The present invention may realize a transistor having various structures.

For example, a bottom gate-bottom contact device may include a gate insulating layer on the gate electrode, a source electrode and a drain electrode on the gate insulating layer, and a semiconductor layer contacting the source and drain electrodes on the gate insulating layer.

A field effect transistor including the aligned oxide semiconductor wire according to the embodiment satisfies the above requirement, and thus another embodiment of the present invention may provide the following field effect transistor array.

Specifically, the field effect transistor may be an oxide semiconductor wire field effect transistor array having a bottom-gate structure including:

a gate electrode formed on a substrate;

a gate insulating layer formed on the gate electrode;

an aligned oxide semiconductor wire pattern formed on the gate insulating layer; and

a source/drain electrode formed on the aligned oxide semiconductor wire pattern.

Alternatively, the field effect transistor array may be an oxide semiconductor wire field effect transistor array having a top-gate structure including:

a source/drain electrode formed on a substrate;

an aligned oxide semiconductor wire pattern formed on the source/drain electrode;

a gate insulating layer formed on the aligned oxide semiconductor wire pattern; and

a gate electrode formed on the gate insulating layer.

The field effect transistor array including the aligned oxide semiconductor wire according to the embodiment has high charge mobility and a high on/off current, and is appropriate for a flat or flexible display, a memory, a direct circuit, a chemical and biological sensor, and an RFID.

The field effect transistor array according to the embodiment may be manufactured as follows. That is, a method of manufacturing a field effect transistor array having a bottom-gate structure including the oxide semiconductor wire includes:

forming a gate electrode on a substrate;

forming a gate insulating layer on the substrate on which the gate electrode is formed;

dissolving an oxide semiconductor precursor and an organic polymer in distilled water or an organic solvent to provide a composite solution of an oxide semiconductor precursor/organic polymer;

continuously discharging the composite solution of the oxide semiconductor precursor/organic polymer in a vertical upper direction from a substrate to align an oxide semiconductor precursor/organic polymer composite wire on the gate insulating layer;

heating the oxide semiconductor precursor/organic polymer composite wire to remove the organic polymer and converting the oxide semiconductor precursor into an oxide semiconductor to form an aligned oxide semiconductor wire pattern; and

forming a source/drain electrode on the aligned oxide semiconductor wire pattern.

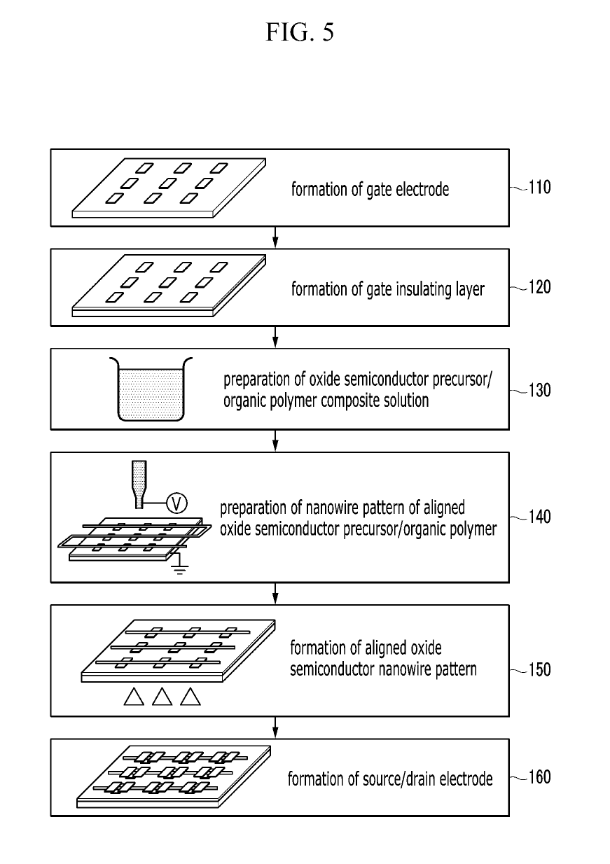

FIG. 5 is a flowchart showing a method of manufacturing a field effect transistor with a bottom-gate structure and including the oxide semiconductor wire.

In another embodiment, a method of manufacturing a field effect transistor array having a top-gate structure is provided, including:

forming a source/drain electrode on a substrate;

dissolving an oxide semiconductor precursor and an organic polymer in distilled water or an organic solvent to provide a composite solution of an oxide semiconductor precursor/organic polymer;

discharging the composite solution of the oxide semiconductor precursor/organic polymer in a vertical upper direction from the source/drain electrode to align an oxide semiconductor precursor/organic polymer composite wire;

heating the aligned oxide semiconductor precursor/organic polymer composite wire to remove the organic polymer and converting the oxide semiconductor precursor into an oxide semiconductor to form an aligned oxide semiconductor wire pattern;

forming a gate insulating layer on the aligned oxide semiconductor wire pattern; and

forming a gate electrode on the gate insulating layer.

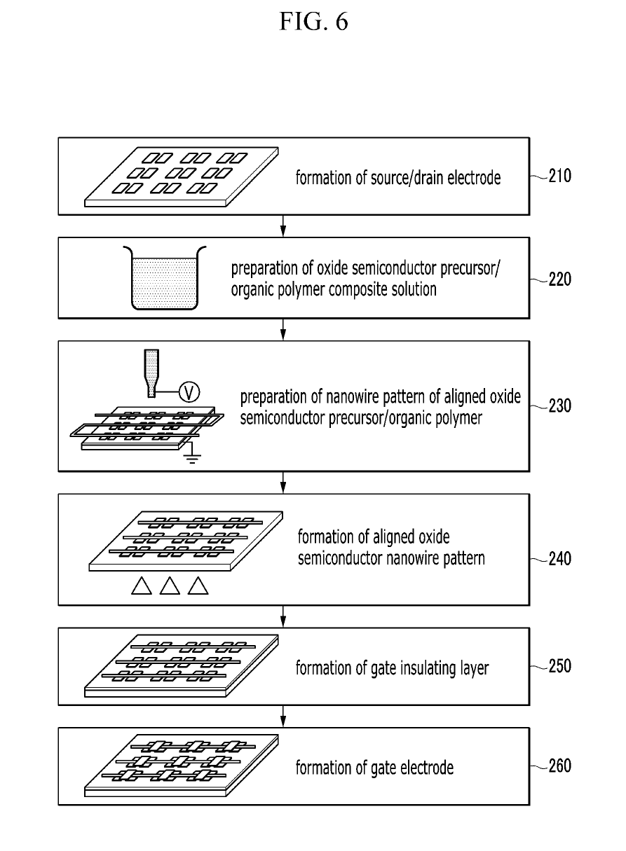

FIG. 6 is a flowchart showing a method of manufacturing a field effect transistor with a top-gate structure including the oxide semiconductor wire.

In the method of manufacturing the field effect transistor array, the oxide semiconductor precursor/organic polymer composite solution is discharged at a position 10 μm to 20 mm apart from the gate insulating layer or the source/drain electrode in a vertical upper direction.

The formation of the aligned oxide semiconductor wire pattern may include heat-treating the oxide semiconductor precursor/organic polymer composite nanowire at a temperature ranging from 100° C. to 900° C. for 1 minute to 24 hours.

The alignment of the oxide semiconductor precursor/organic polymer composite wire may be performed by using an electric field auxiliary robotic nozzle printer.

A method of forming an aligned oxide semiconductor wire pattern and the electric field auxiliary robotic nozzle printer are the same as above, and thus will not be illustrated in detail again.

The oxide semiconductor wire formed on the field effect transistor array may have a diameter ranging from 10 nm to 1000 nm, and may be long within a meter range.

The formation of the gate electrode and the gate insulating layer may be performed in a method selected from, independently, drop casting, spin-coating, dip-coating, E-beam evaporation, thermal evaporation, printing, soft-lithography, and sputtering.

The gate electrode may be selected from a group consisting of a metal, a conductive polymer, a carbon material, a doped semiconductor, and a combination thereof.

Specifically, the metal may be selected from the group consisting of Al, Si, Sc, Ti, V, Cr, Mn, Fe, Y, Zr, Nb, Mo, Ta, W, Ni, Cu, Ag, Au, and Cu, the conductive polymer may include polyethylenedioxythiophene (PEDOT), polyaniline, polypyrrole, or the like, the carbon material may include graphene, carbon nanotubes, graphite amorphous carbon, or the like, and the doped semiconductor may include doped silicon (doped-Si), doped germanium (doped-Ge), and the like.

A thickness of the gate electrode may be 1 nm to 1 μm, and more preferably 3 nm to 500 nm.

The gate insulating layer may be selected from a self-assembled molecule, an insulation polymer, an inorganic oxide, a polymer electrolyte, and a combination thereof, that includes at least one functional group selected from the group consisting of an acid group such as a carboxyl group (—COOH), a hydroxyl group (—OH), and the like, a thiol group (—SH), and a trichlorosilane group (—SiCl₃). Specifically, the insulation polymer may be polyvinyl alcohol (PVA), polyethylene oxide (PEO), polystyrene (PS), polycaprolactone (PCL), polyacrylonitrile (PAN), poly(methyl methacrylate) (PMMA), polyimide, poly(vinylidene fluoride) (PVDF), polyaniline (PANI), polyvinylchloride (PVC), nylon, poly(acrylic acid), poly(chloro styrene), poly(dimethyl siloxane), poly(ether imide), poly(ether sulfone), poly(alkyl acrylate), poly(ethyl acrylate), poly(ethyl vinyl acetate), poly(ethyl-co-vinyl acetate), poly(ethylene terephthalate), poly(lactic acid-co-glycolic acid), a poly(methacrylate) salt, poly(methyl styrene), a poly(styrene sulfonate) salt, poly(styrene sulfonyl fluoride), poly(styrene-co-acrylonitrile), poly(styrene-co-butadiene), poly(styrene-co-divinyl benzene), polyvinyl acetate), polylactide, polyvinyl alcohol), polyacrylamide, polybenzimidazole, polycarbonate, poly(dimethylsiloxane-co-polyethyleneoxide), poly(etheretherketone), polyethylene, polyethyleneimine, polyisoprene, polylactide, polypropylene, polysulfone, polyurethane, poly(vinylpyrrolidone), CYTOP (an amorphous fluorine polymer (amorphous fluoropolymer) made by Asahi glass), or a combination thereof, and the inorganic oxide may be silicon dioxide (SiO₂), aluminum oxide (Al₂O₃), tantalum oxide (Ta₂O₅), titanium oxide (TiO₂), strontium titannate (SrTiO₃), zirconium oxide (ZrO₂), hafnium oxide (HfO₂), hafnium silicate (HfSiO₄), lanthanum oxide (La₂O₃), yttrium oxide (Y₂O₃), lanthanum aluminate (a-LaAlO₃), or a combination thereof.

In addition, the polymer electrolyte may be an ionic liquid such as LiClO₄, LiTFSI (lithium-bis(trifluoromethylsulfonyl)imide), LiPSS (lithium poly(styrene sulfonate)), [EMIM][TFSI] (1-ethyl-3-methylimidazolium bis(trifluoromethylsulfonyl)imide), [BMIM][PF₆] (1-butyl-3-methylimidazolium hexafluorophosphate), [EMIM][OctOSO₃] (1-ethyl-3-methylimidazolium n-octylsulfate), and the like, PEO, PS-PEO-PS, PS-PMMA-PS, or PEGDA (poly(ethylene glycol) diacrylate), or a combination thereof.

A thickness of the gate insulating layer may be 1 nm to 10 μm, and more preferably 3 nm to 500 nm.

In general, the source and drain may include a transparent oxide semiconductor having a conductive electrode and a capacitance charge-injecting scheme for controlling and/or transforming a source-drain current.

The source/drain electrode may be selected from the group consisting of a metal, a conductive polymer, a carbon material, a doped semiconductor material, and a combination thereof.

The metal may be selected from the group consisting of Pt, Al, Si, Sc, Ti, V, Cr, Mn, Fe, Y, Zr, Nb, Mo, Ta, W, Ni, Cu, Ag, Au, and Cu, the conductive polymer may include polyethylenedioxythiophene (PEDOT), polyaniline, polypyrrole, or a combination thereof, and the carbon material may include graphene, carbon nanotubes, graphite amorphous carbon, and the like.

The source/drain electrode may be formed in a method selected from drop-casting, spin-coating, dip-coating, E-beam evaporation, thermal evaporation, printing, and sputtering.

A thickness of the source/drain electrode may be 1 nm to 1 μm, and more preferably 3 nm to 500 nm.

The gate electrode should have a gap of the source/drain electrode.

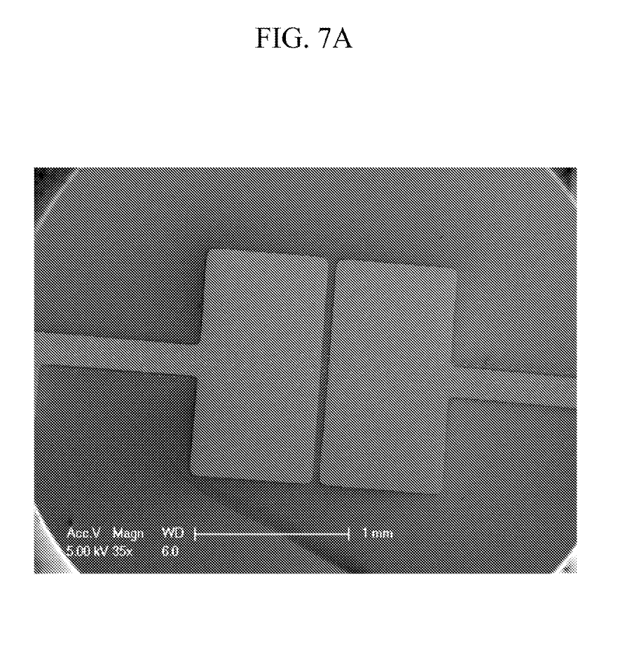

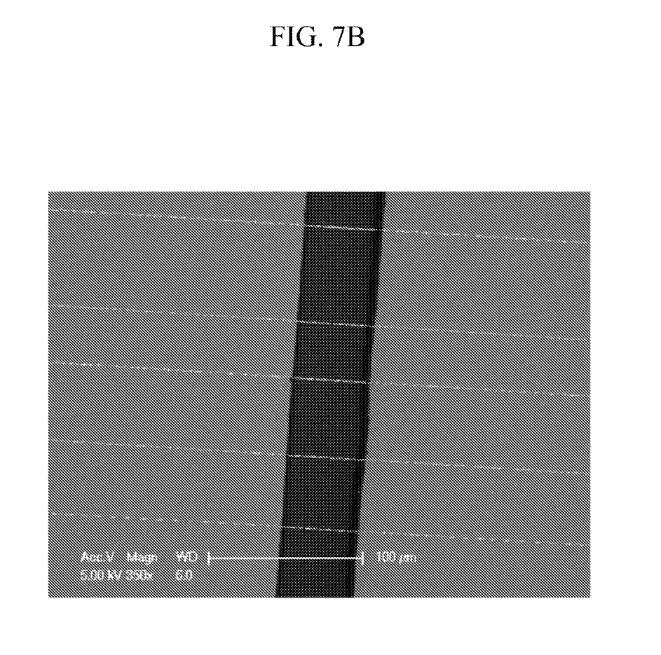

FIGS. 7A and 7B are SEM photographs showing a zinc oxide wire formed on a source/drain electrode, and the zinc oxide wire is aligned in a direction parallel therewith.

The electronic device according to another exemplary embodiment may be a gas sensor array including the aligned oxide semiconductor wire according to the embodiment.

A gas sensor is used in vast areas such as chemistry, medicine, pharmacy, environment, and the like to monitor toxic materials and contamination materials in the air and our living environment. A metal oxide gas sensor that senses gas through electrical conductivity change when it reacts with a gas has high sensitivity, a high response speed, high stability, and the like, as well as being inexpensive among various gas sensors, and thus is widely used.

This gas sensor may include the aligned oxide semiconductor wire according to the embodiment. In other words, the gas sensor array according to the embodiment may be manufactured by forming a plurality of a pairs of electrodes including a source electrode and a drain electrode on a substrate and then forming an aligned oxide semiconductor wire pattern on each source and drain electrode in a method according to the embodiment.

The oxide semiconductor wire pattern on each source and drain electrode may be horizontally aligned. The term ‘horizontally’ indicates horizontally aligned with the source and drain electrodes. In addition, each source and drain electrode in a plurality of electrode pairs may respectively form a different metal oxide semiconductor wire pattern.

A method of forming the aligned oxide semiconductor wire pattern, a method of forming the source/drain electrodes, materials thereof, and the like may be the same as aforementioned, and will not be illustrated in detail again.

According to the embodiment of the present invention, a gas sensor having improved charge mobility may be provided. In addition, a method of manufacturing an oxide semiconductor wire according to the embodiment may precisely adjust the position and direction of the oxide semiconductor wire and provide a nanowire gas sensor array having a large area and high performance, and particularly, a nanowire gas sensor at a faster speed, since the oxide semiconductor nanowire is formed faster than a conventional method by using the electric field robotic nozzle printer. In addition, the method of manufacturing an oxide semiconductor wire may improve gas-sensing efficiency of the gas sensor according to the embodiment, since the oxide semiconductor wire has a small diameter and thus a large surface, and brings about nano-patterning effects at room temperature under atmospheric pressure.

Hereinafter, the embodiments are illustrated in more detail with reference to examples. These examples, however, are not in any sense to be interpreted as limiting the scope of the invention.

### EXAMPLES

### Example 1

### Formation of Horizontally Aligned Zinc Oxide Nanowire

### Pattern

A horizontally-aligned zinc oxide nanowire pattern was manufactured according to the following method.

First, zinc acetate dihydrate (Zn(CH₃(COO)₂.2H₂O) (80 wt %) and polyvinyl alcohol (PVA) (20 wt %) were dissolved in distilled water, preparing a zinc oxide precursor/PVA solution. The precursor/PVA solution had a concentration of 10 wt %. The zinc oxide precursor/PVA solution was put in a syringe of an electric field auxiliary robotic nozzle printer, and then discharged from a nozzle thereof while a voltage of about 2.0 kV was applied thereto. Then, a zinc oxide precursor/PVA composite nanowire pattern aligned on a substrate was formed by a collector moved by a robot stage.

The nozzle had a diameter of 100 μpm, and the applied voltage was 2.1 kV. The nozzle and the collector constantly maintained a distance therebetween of 5 mm. The robot stage moved 50 μm in a Y-axis direction and 15 cm in an X-axis direction. The collector had a size of 20 cm×20 cm, and the substrate on the collector had a size of 7 cm×7 cm. The substrate was a silicon (Si) wafer having a 100 nm-thick silicon oxide (SiO₂) layer.

The aligned zinc oxide precursor/PVA nanowire pattern was heated at 500° C. in a furnace for 4 hours, forming a zinc oxide nanowire pattern formed of aligned nanograins.

### Example 2

### Formation of Aligned Copper Oxide Nanowire Pattern

An aligned copper oxide nanowire pattern was manufactured in the following method.

First of all, copper trifluoroacetate hydrate (Cu(CO₂CF₃)₂.nH₂O, 25 wt %) and polyvinyl pyrrolidone (PVP) (10 wt %) were dissolved in dimethyl formamide and tetrahydrofuran, preparing a copper oxide precursor/PVP solution. The precursor/PVP solution had a concentration of 31 wt %. The copper oxide precursor/PVP solution was put in a syringe of an electric field auxiliary robotic nozzle printer and then discharged from a nozzle thereof, while a voltage of about 0.5 kV was applied thereto. Then, an aligned copper oxide precursor/PVP composite nanowire pattern was formed on a substrate of a collector moved by a robot stage.

Herein, the nozzle had a diameter of 100 μm, and the applied voltage was 0.5 kV. The nozzle and the collector were constantly maintained at a distance of 7 mm therebetween. The robot stage moved 200 μm in a Y-axis direction and 15 cm in an X-axis direction. The collector had a size of 20 cm×20 cm, and the substrate on the collector had a size of 7 cm×7 cm. The substrate was a silicon (Si) wafer having a 300 nm-thick silicon oxide (SiO₂) layer.

The aligned copper oxide precursor/PVP nanowire pattern was heated at 450° C. in a furnace for one hour, forming an aligned copper oxide nanowire pattern.

### Example 3

### Manufacture of Oxide Semiconductor Nanowire Inverter

The aligned zinc oxide nanowire pattern and the aligned copper oxide nanowire pattern according to Examples 1 and 2 were used to manufacture an oxide semiconductor nanowire inverter.

First, a zinc oxide nanowire pattern and a copper oxide nanowire pattern were manufactured by using a silicon (Si) wafer having a 300 nm-thick silicon oxide (SiO₂) layer as a substrate according to the same methods as Examples 1 and 2. Herein, the substrate had a size of 2.5 cm×2.5 cm, and the silicon (Si) and the silicon oxide layer (SiO₂) were respectively used as a gate and a gate insulating layer. A source/drain/output electrode was formed by thermally depositing gold to be 100 nm thick on the nanowire patterns.

The manufactured oxide semiconductor nanowire inverters respectively showed a gain value of 7.5, 12.7, and 16.5 about each drain voltage of 30, 40, and 50 V.

### Example 4

### Manufacture of Zinc Oxide Nanowire Transistor Array Having Bottom-Gate Structure

A zinc oxide nanowire transistor having a bottom-gate structure with an area of 7 cm×7 cm was manufactured according to the following method.

First, zinc acetate dihydrate (Zn(CH₃(COO)₂.2H₂O) (80 wt %) and polyvinyl alcohol (PVA) (20 wt %) were dissolved in distilled water, preparing a zinc oxide precursor/PVA solution. The precursor/PVA solution had a concentration of 10 wt %. The prepared zinc oxide precursor/PVA solution was put in a syringe of an electric field auxiliary robotic nozzle printer and discharged from a nozzle thereof while a voltage of about 2.0 kV was applied to the nozzle. Then, an aligned zinc oxide precursor/PVA composite nanowire pattern was formed on a substrate of a collector moved by a robot stage.

Herein, the nozzle had a diameter of 100 μm, and the applied voltage was 2.1 kV. The nozzle and the collector constantly maintained a distance of 5 mm therebetween. The robot stage moved 50 μm in a Y-axis direction and 15 cm in an X-axis direction.

The collector had a size of 20 cm×20 cm, and the substrate on the collector had a size of 7 cm×7 cm. The substrate was a silicon (Si) wafer having a 100 nm-thick silicon oxide (SiO₂) layer. Herein, the silicon (Si) and the silicon oxide (SiO₂) layer were respectively a gate and a gate insulating layer.

The aligned zinc oxide precursor/PVA nanowire pattern was heated at 500° C. for 4 hours in a furnace, forming an aligned zinc oxide nanowire pattern. Then, a source/drain electrode was thermally formed thereon by depositing gold to be 100 nm thick. In this way, 144 zinc oxide nanowire transistor devices in lo total were formed on the substrate.

### Examples 5 to 7

### Manufacture of Zinc Oxide Nanowire Transistor Array Having Bottom-gate Structure

Each zinc oxide nanowire transistor having a bottom-gate structure according to Examples 5 to 7 was manufactured in the same method as Example 4, except for heat-treating the aligned zinc oxide precursor/PVA nanowire pattern at 500° C. for 6 hours, 8 hours, and 10 hours, respectively, in a furnace.

### Example 8

### Manufacture of Zinc Oxide Nanowire Transistor Array Having Top-gate Structure

A zinc oxide nanowire transistor array having a top-gate structure with an area of 7 cm×7 cm was manufactured in a method of manufacturing a nanowire field effect transistor having a top-gate structure.

A source/drain electrode was formed by thermally depositing gold to be 100 nm thick on a silicon (Si) wafer having a 100 nm thick silicon oxide (SiO₂) layer. This product was used as a substrate.

A zinc oxide precursor/PVA solution was prepared by dissolving zinc acetate dihydrate (Zn(CH₃(COO)₂.2H₂O) (80 wt %) and PVA (20 wt %) in distilled water. The zinc oxide precursor/PVA solution had a concentration of 10 wt %. The prepared zinc oxide precursor/PVA solution was put in a syringe of an electric field auxiliary robotic nozzle printer and discharged from a nozzle thereof, while a voltage of about 2.0 kV was applied to the nozzle. An aligned zinc oxide precursor/PVA composite nanowire pattern was formed on a substrate of a collector moved by a robot stage.

The nozzle had a diameter of 100 μm and constantly maintained a distance of 5 mm with the collector, and the applied voltage was 2.2 kV. The robot stage moved 50 μm in a Y-axis direction and 15 cm in an X-axis direction. The collector had a size of 20 cm×20 cm, and the substrate on the collector had a size of 7 cm×7 cm.

The aligned zinc oxide precursor/PVA nanowire pattern was heated at 500° C. for 4 hours in a furnace, forming an aligned zinc oxide nanowire pattern. Then, a gate insulating layer was formed thereon by spin-coating polystyrene (PS) to be 50 nm thick. A gate electrode was formed by depositing titanium to be 100 nm thick on the gate insulating layer.

### Examples 9 to 11

### Manufacture of Zinc Oxide Nanowire Transistor Array Having Top-Gate Structure

Each transistor according to Examples 9 to 11 was manufactured in the same method as Example 8, except for heating an aligned zinc oxide precursor/PVA nanowire pattern at 500° C. for 6 hours, 8 hours, and 10 hours, respectively, in a furnace.

### Experimental Example 1

### Charge Mobility and Current On/Off Ratio

The charge mobility and current on/off ratio of the transistors according to Examples 4 to 11 were measured.

The transistors according to Examples 4 to 7 had average mobility of about 0.1 cm²/Vs at a drain voltage of 40 V and a gate voltage of 25 V, and an average on/off ratio of about 10⁴.

The transistors according to Examples 8 to 11 had average mobility of about 0.12 cm²/V·s at a drain voltage of 40 V and a gate voltage of 27.5 V, and an average on/off ratio of about 10^{4.}

### Example 12

### Zinc Oxide Nanowire Single Gas Sensor

A zinc oxide nanowire single gas sensor having an area of 1 cm×1 cm was manufactured according to the following method.

A single source/drain electrode was formed by depositing Pt to be 100 nm thick through photolithography and thermal deposition on a SiO₂/Si substrate (a silicon wafer coated with a 100 nm-thick silicon oxide layer). A zinc oxide precursor/PVP solution was prepared by dissolving a zinc oxide precursor and PVP (polyvinylpyrrolidone) in dimethyl formamide and trichloroethylene. The zinc oxide precursor/PVP solution was put in a syringe of an electric field auxiliary robotic nozzle printer and discharged from a nozzle thereof, while a voltage of about 1 kV was applied to the nozzle.

A zinc oxide precursor/PVP composite nanowire pattern aligned on a substrate of a collector moved by a robot stage was formed. Herein, the nozzle had a diameter of 100 μm and maintained a distance of 6.5 mm from the collector, and the applied voltage was 1 kV. The robot stage moved 50 μm in a Y-axis direction and 15 cm in an X-axis direction.

The collector had a size of 20 cm×20 cm, and the substrate on the collector had a size of 1 cm×1 cm. Then, the aligned zinc oxide precursor/PVP nanowire pattern was heated at 500° C. for 1 hour in a furnace, forming an aligned zinc oxide nanowire pattern.

### Example 13

### Manufacture of Gas Sensor Array including Various Metal Oxide Nanowire

A gas sensor array having an area of 1.5 cm×1.5 cm and respectively consisting of a different metal oxide (ZnO, SnO₂, In₂O₃, WO₃) nanowire was manufactured by using a method of manufacturing a large area nanowire gas sensor array.

First, a pair of a source electrode and a drain electrode was formed by depositing Pt to be 100 nm thick on the SiO₂/Si substrate (a silicon wafer coated with a 100 nm-thick silicon oxide layer) through photolithography and thermal deposition. Then, a zinc oxide precursor/PVP solution was prepared by dissolving a zinc oxide precursor and PVP (polyvinylpyrrolidone) in dimethyl formamide and trichloroethylene. The prepared zinc oxide precursor/PVP solution was put in a syringe of an electric field auxiliary robotic nozzle printer and discharged from a nozzle thereof, while a voltage of about 1 kV was applied to the nozzle. In this way, an aligned zinc oxide precursor/PVP composite nanowire pattern was formed on a substrate of a collector moved by a robot stage.

A tin oxide precursor/PVP solution was prepared by dissolving a tin oxide precursor and PVP (polyvinylpyrrolidone) in dimethyl formamide and ethanol. The prepared tin oxide precursor/PVP solution was put in a syringe of an electric field auxiliary robotic nozzle printer and then discharged from a nozzle thereof, while a voltage of about 0.6 kV was applied to the nozzle. In this way, a tin oxide precursor/PVP composite nanowire pattern aligned on a substrate of a collector moved by a robot stage was formed.

An indium oxide precursor/PVP solution was prepared by dissolving an indium oxide precursor and PVP (polyvinylpyrrolidone) in dimethyl formamide and tetrahydrofuran. The prepared indium oxide precursor/PVP solution was put in a syringe of an electric field auxiliary robotic nozzle printer and discharged from a nozzle thereof, while a voltage of about 0.7 kV was applied to the nozzle. In this way, an indium oxide precursor/PVP composite nanowire pattern aligned on a substrate of a collector moved by a robot stage was formed.

A tungsten oxide precursor/PVP solution was prepared by dissolving a tungsten oxide precursor and PVP (polyvinylpyrrolidone) in dimethyl formamide and ethanol. The prepared tungsten oxide precursor/PVP solution was put in a syringe of an electric field auxiliary robotic nozzle printer and discharged from a nozzle thereof while a voltage of about 0.7 kV was applied to the nozzle. In this way, a tungsten oxide precursor/PVP composite nanowire pattern aligned on a substrate of a collector moved by a robot stage was formed.

The aligned zinc oxide precursor/PVP, tin oxide precursor/PVP, indium oxide precursor/PVP, and tungsten oxide precursor/PVP nanowire patterns were heated at 500° C. for 1 hour in a furnace, forming each aligned zinc oxide, tin oxide, indium oxide, and tungsten oxide nanowire pattern.

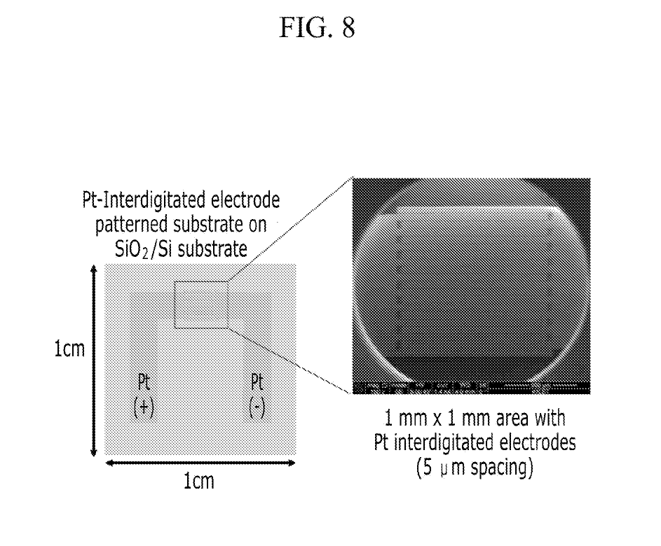

FIG. 8 is a photomicrograph showing a substrate manufactured according to Example 12 of the present invention.

Referring to FIG. 8, a metal oxide nanowire pattern horizontally aligned on source and drain electrodes formed by depositing Pt on a SiO₂/Si substrate was formed.

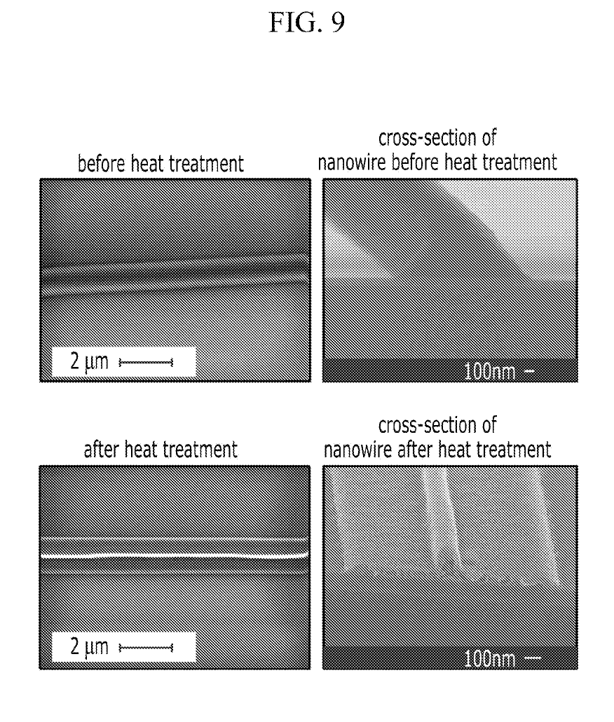

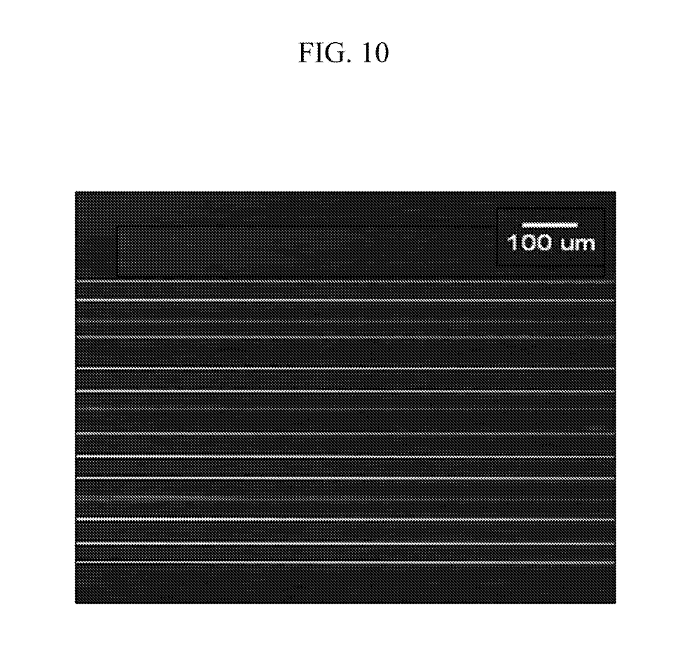

FIG. 9 shows scanning electron microscope (SEM) photographs of a ZnO nanowire according to Example 13 of the present invention.

Referring to FIG. 9, the metal oxide nanowire had a smaller diameter after heat-treatment. This metal oxide nanowire showed improved gas sensitivity as it had a larger contact area with the gas.

FIG. 10 is a scanning electron microscope (SEM) photograph showing the aligned ZnO nanowire according to Example 13 of the present invention.

Referring to FIG. 10, the metal oxide nanowire according to the present invention was aligned in a horizontal direction.

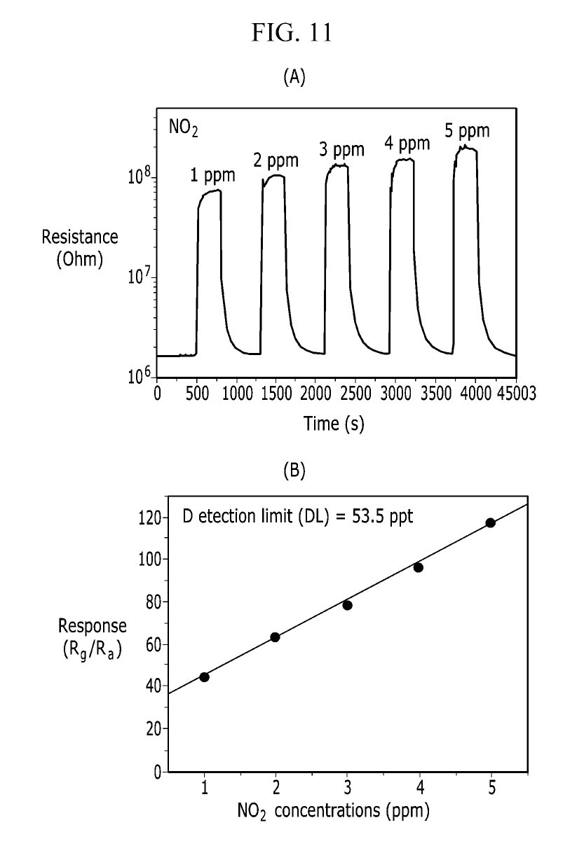

FIG. 11 is a graph showing a ZnO nanowire gas sensor result regarding NO₂ gas according to Example 13 of the present invention.

The zinc oxide nanowire gas sensor formed on a substrate had sensitivity of about 100 regarding NO₂ (g) and showed a detection limit of about 53.5 ppt.

Referring to FIG. 11, a gas sensor according to an exemplary embodiment of the present invention showed high sensitivity about NO₂ and also increasing sensitivity as the concentration of the NO₂ was increased.

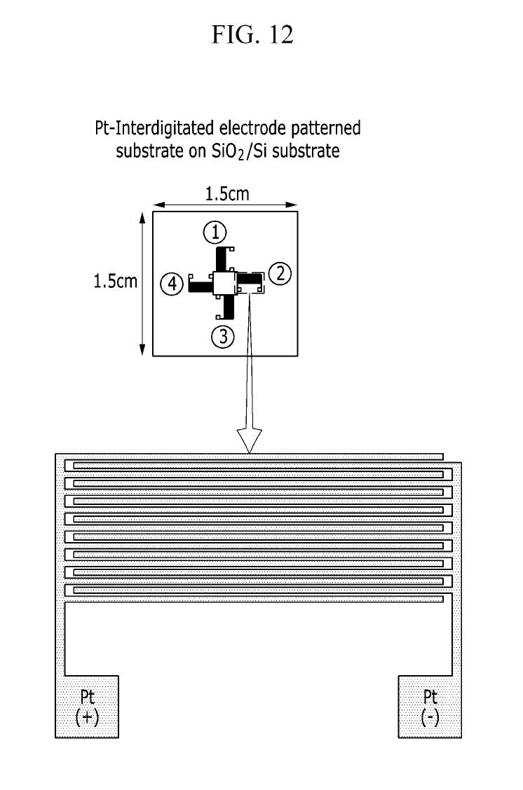

FIG. 12 is a substrate for a nanowire array gas sensor according to Example 13 of the present invention.

Referring to FIG. 12, more than one pair of a source electrode and a drain electrode were formed by depositing Pt on a SiO₂/Si substrate, and a metal oxide (\textcircled{1}-zinc oxide, \textcircled{2}-tin oxide, \textcircled{3}-indium oxide, \textcircled{4}-tungsten oxide) was formed thereon.

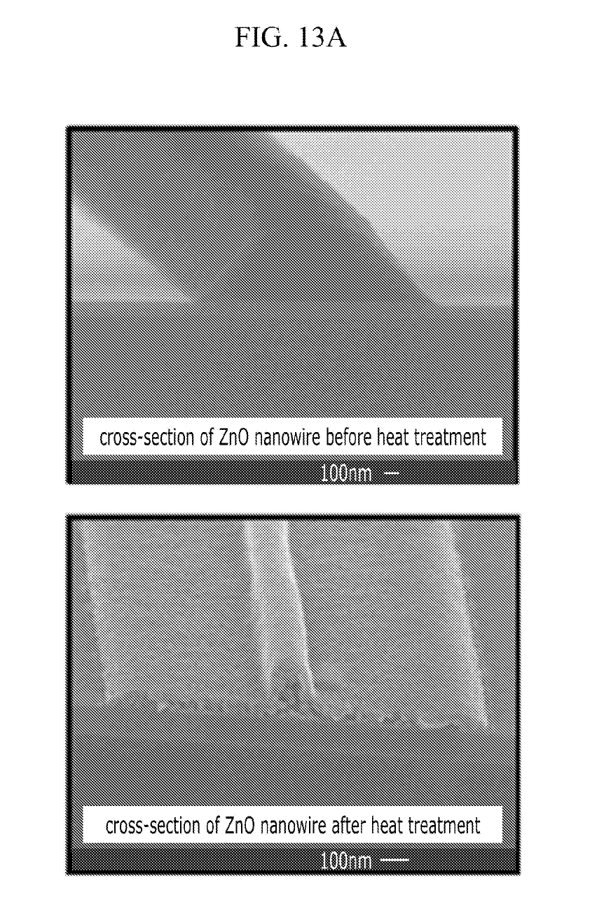

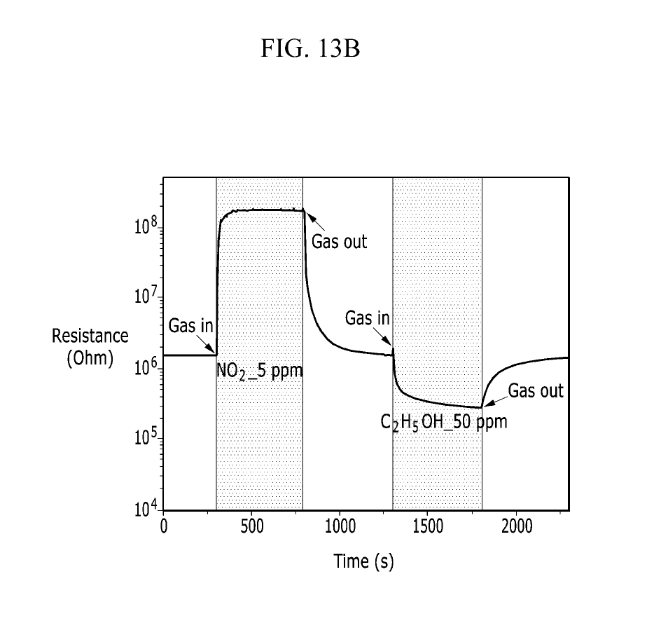

FIG. 13A is a scanning electron microscope (SEM) photograph showing the ZnO nanowire according to Example 13 of the present invention, and FIG. 13B is a graph showing the sensitivity result of the ZnO nanowire gas sensor according to Example 2 of the present invention regarding C₂H₅OH and NO₂ gases.

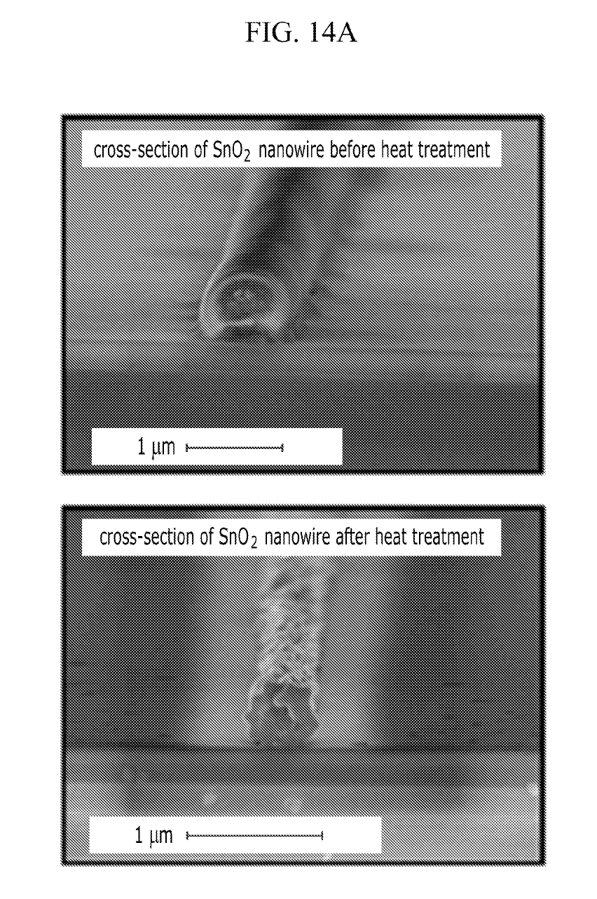

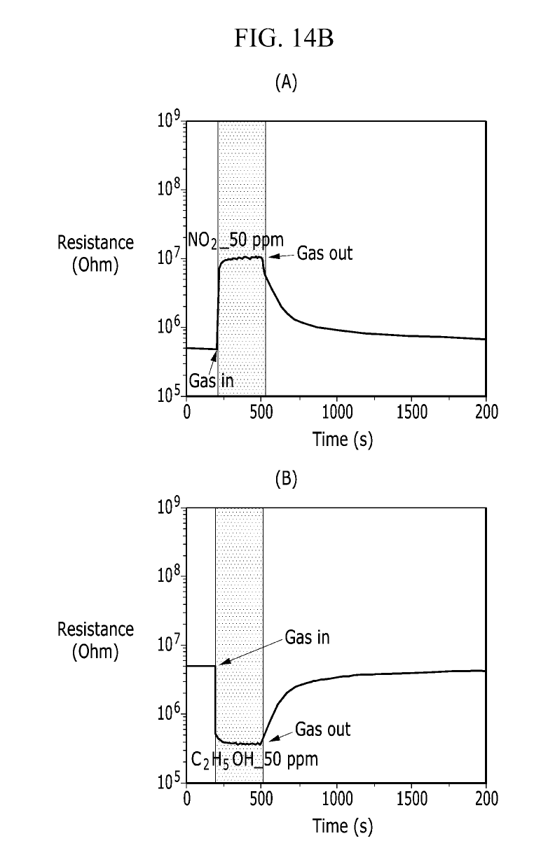

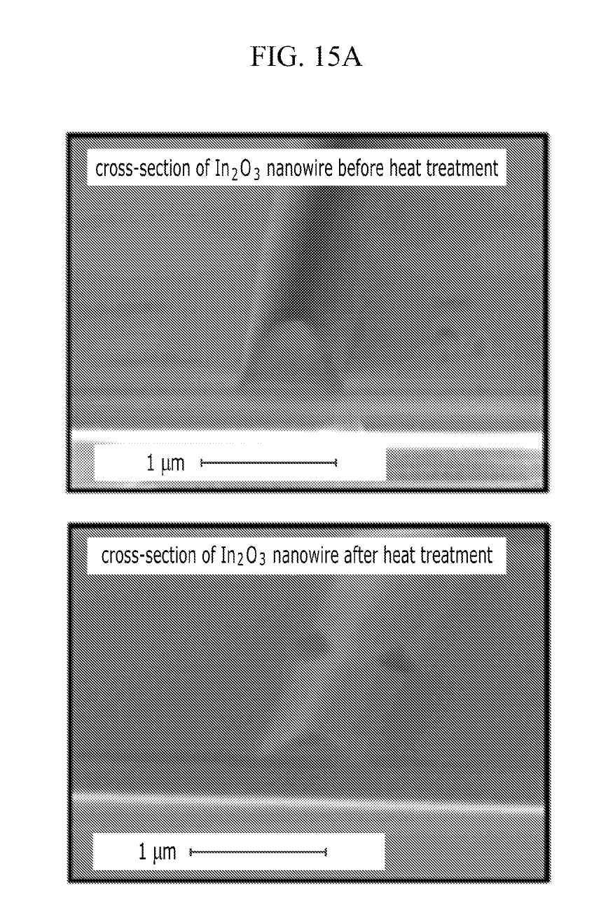

FIG. 14A shows scanning electron microscope (SEM) photographs of the SnO₂ nanowire according to Example 13 of the present invention, and FIG. 14B shows graphs of the sensitivity result of the SnO₂ nanowire gas sensor according to Example 13 of the present invention regarding C₂H₅OH and NO₂ gases.

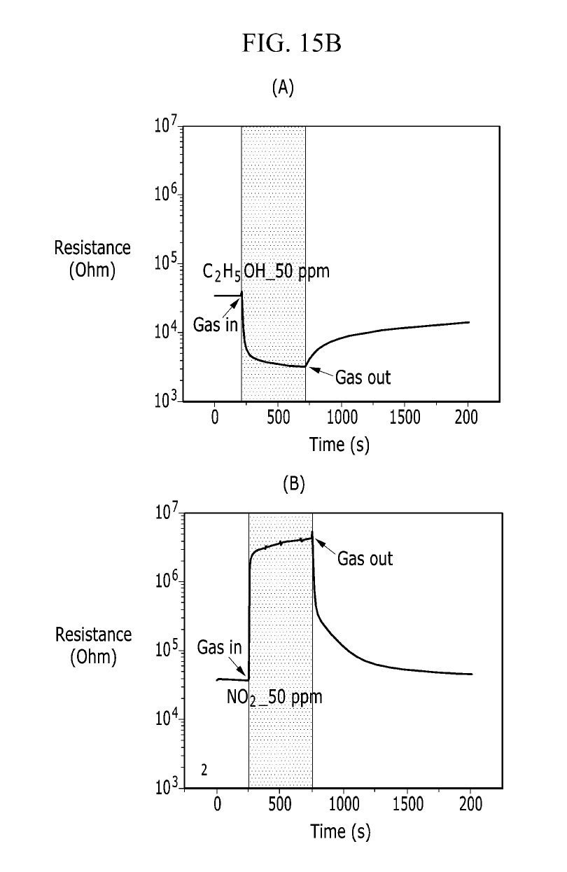

In addition, FIG. 15A shows scanning electron microscope (SEM) photographs of the In₂O₃ nanowire according to Example 13 of the present invention, FIG. 15B shows graphs of sensitivity results of the In₂O₃ nanowire gas sensor according to Example 13 of the present invention regarding C₂H₅OH and NO₂ gases.

Referring to FIGS. 13A and 13B, when the characteristics of the zinc oxide (ZnO) nanowire gas sensor were measured, the zinc oxide (ZnO) nanowire gas sensor showed sensitivity of about 116 regarding NO₂ gas and sensitivity of about 6 regarding C₂H₅OH gas.

Referring to FIGS. 14A and 14B, when the characteristics of the tin oxide (SnO₂) nanowire gas sensor were measured, the gas sensor showed sensitivity of about 21 regarding the NO₂ gas and sensitivity of about 13 regarding the C₂H₅OH gas.

Referring to FIGS. 15A and 15B, when the characteristics of the indium oxide (In₂O₃) nanowire gas sensor were measured, the gas sensor showed sensitivity of about 114 regarding the NO₂ gas and sensitivity of about 11 regarding the C₂H₅OH gas.

Accordingly, the gas sensor including the metal oxide nanowire according to the embodiment of the present invention showed high sensitivity regarding NO₂ gas and C₂H₅OH gas.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims. Therefore, the aforementioned embodiments should be understood to be exemplary but not limiting the present invention in any way.

### DESCRIPTION OF SYMBOLS

| | |
|---|---|
| 10: solution storage unit | 20: discharge controller |
| 30: nozzle | 40: voltage applying unit |
| 50: collector | 51: grounding unit |
| 60: robot stage | 61: base plate |

| | |
|---|---|
| 70: micro-distance controller | 71: jog |

1. A method for forming an aligned oxide semiconductor wire pattern, comprising:
dissolving an oxide semiconductor precursor and an organic polymer in distilled water or an organic solvent to provide a composite solution of an oxide semiconductor precursor/organic polymer;
continuously discharging the composite solution of the oxide semiconductor precursor/organic polymer in a vertical upper direction from a substrate to align an oxide semiconductor precursor/organic polymer composite wire on the substrate; and
heating the oxide semiconductor precursor/organic polymer composite wire to remove the organic polymer and converting the oxide semiconductor precursor into an oxide semiconductor to form an aligned oxide semiconductor wire pattern.

2. The method of claim 1, wherein the discharging of the oxide semiconductor precursor/organic polymer composite solution comprises discharging the composite solution at a position 10 μm to 20 mm apart from the substrate in a vertical upper direction.

3. The method for of claim 1, wherein the aligned oxide semiconductor wire pattern is formed by heating the oxide semiconductor precursor/organic polymer composite wire at a temperature ranging from 100° C. to 900° C. for 1 minute to 24 hours.

4. The method of claim 1, wherein aligning the oxide semiconductor precursor/organic polymer composite wire is performed by an electric field auxiliary robotic nozzle printer, wherein the electric field auxiliary robotic nozzle printer comprises:
i) a solution storage unit receiving an oxide semiconductor precursor/organic polymer composite solution;
ii) a nozzle unit configured to discharge the solution supplied from the solution storage unit;
iii) a voltage applying unit configured to apply a high voltage to the nozzle;
iv) a collector fixing the substrate;
v) a robot stage configured to transfer the collector in a horizontal direction;
vi) a micro-distance controller configured to transfer the collector in a vertical direction; and
vii) a base plate supporting the collector.

5. The method of claim 4, wherein
the aligning the oxide semiconductor precursor/organic polymer composite wire comprises:
i) supplying the oxide semiconductor precursor/organic polymer composite solution to the solution storage unit of the electric field auxiliary robotic nozzle printer; and
ii) applying a high voltage to the nozzle through the voltage applying unit of the electric field auxiliary robotic nozzle printer to discharge the oxide semiconductor precursor/organic polymer composite solution from the nozzle,
wherein when the oxide semiconductor precursor/organic polymer composite solution is discharged and forms a Taylor cone at the end of the nozzle, a continuously connected oxide semiconductor precursor/organic polymer composite wire is aligned on a substrate by moving the substrate while the oxide semiconductor precursor/organic polymer composite solution is discharged in a vertical upper direction from the substrate to form a continuously connected wire.

6. The method of claim 1, wherein the substrate is selected from the group consisting of an insulation material, a metal material, a carbon material, a composite material of a conductor and an insulation layer, and a combination thereof.

7. The method of claim 1, wherein the oxide semiconductor precursor is selected from the group consisting of a zinc oxide precursor, an indium oxide precursor, a tin oxide precursor, a gallium oxide precursor, a tungsten oxide precursor, an aluminum oxide precursor, a titanium oxide precursor, a vanadium oxide precursor, a molybdenum oxide precursor, a copper oxide precursor, a nickel oxide precursor, an iron oxide precursor, a chromium oxide precursor, a bismuth oxide precursor, and a combination thereof.

8-21. (canceled)

22. The method of claim 1, wherein the organic polymer is selected from the group consisting of polyvinyl alcohol (PVA), polyethylene oxide (PEO), polystyrene (PS), polycaprolactone (PCL), polyacrylonitrile (PAN), poly(methyl methacrylate) (PMMA), polyimide, poly(vinylidene fluoride) (PVDF), polyaniline (PANI), polyvinylchloride (PVC), nylon, poly(acrylic acid), poly(chloro styrene), poly(dimethyl siloxane), poly(ether imide), poly(ether sulfone), poly(alkyl acrylate), poly(ethyl acrylate), poly(ethyl vinyl acetate), poly(ethyl-co-vinyl acetate), poly(ethylene terephthalate), poly(lactic acid-co-glycolic acid), a poly(methacrylate) salt, poly(methyl styrene), a poly(styrene sulfonate) salt, poly(styrene sulfonyl fluoride), poly(styrene-co-acrylonitrile), poly(styrene-co-butadiene), poly(styrene-co-divinyl benzene), poly(vinyl acetate), polylactide, poly(vinyl alcohol), polyacrylamide, polybenzimidazole, polycarbonate, poly(dimethylsiloxane-co-polyethyleneoxide), poly(etheretherketone), polyethylene, polyethyleneimine, polyisoprene, polylactide, polypropylene, polysulfone, polyurethane, poly(vinylpyrrolidone), poly(phenylene vinylene), poly(vinyl carbazole), and a combination thereof.

23. The method of claim 1, wherein the organic solvent is selected from the group consisting of dichloroethylene, trichloroethylene or chloroform, chlorobenzene, dichlorobenzene, dichloromethane, styrene, dimethylformamide, dimethylsulfoxide, tetrahydrofuran, xylene, toluene, cyclohexene, 2-methoxyethanol, ethanolamine, acetonitrile, butylalcohol, isopropylalcohol, ethanol, methanol, and acetone, and a combination thereof.

24. The method of claim 1, wherein the oxide semiconductor precursor/organic polymer composite solution is provided by dissolving the oxide semiconductor precursor and the organic polymer in a weight ratio of 10:90 to 97:3 to have a concentration ranging from 1 to 30 wt % in distilled water or the organic solvent.

25. The method of claim 1, wherein a diameter of the oxide semiconductor wire is 10 nm to 1000 μm.

26. An article comprising the aligned oxide semiconductor wire formed according to the method according to claim 1.

27. (canceled)

28. The article according to claim 26, wherein the article is a CMOS sensor.

29. The article according to claim 26, wherein the article is a solar cell.

30. The article according to claim 26, wherein the article is a light emitting transistor.

31. The article according to claim 26, wherein the article is a laser device.

32. The article according to claim 26, wherein the article is a memory.

33. The article according to claim 26, wherein the article is a piezoelectric device.

34-36. (canceled)

37. The article according to claim 26, wherein the article is a field effect transistor.

38. The article according to claim 26, wherein the article is a gas sensor.
